(19) United States
(12) Patent Application Publication
(10) Pub. No.: US 2017/0373192 A1
(43) Pub. Date: Dec. 28, 2017

(54) TRANSISTOR AND SEMICONDUCTOR DEVICE

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd.

(21) Appl. No.: 15/617,341

(22) Filed: Jun. 8, 2017

(30) Foreign Application Priority Data
Jun. 27, 2016 (JP) 2016-127100
Jul. 18, 2016 (JP) 2016-140980

(51) Int. Cl. H01L 29/786; H01L 29/423; H01L 29/66; H01L 29/24

(52) U.S. Cl. CPC H01L 29/7869; H01L 29/78696; H01L 29/24; H01L 29/42384; H01L 29/66969

(57) ABSTRACT

A transistor includes a gate electrode, a first conductor, a second conductor, a gate insulator, and a metal oxide. The gate insulator is located between the gate electrode and the metal oxide. The gate electrode includes a region overlapping with the metal oxide with the gate insulator therebetween. The first conductor and the second conductor each include a region in contact with top and side surfaces of the metal oxide. The metal oxide has a layered structure in which oxides each having a first band gap and oxides each having a second band gap and being adjacent to the oxide having the first band gap are alternately stacked in a thickness direction. The metal oxide includes two or more oxides each having the first band gap. The first band gap is smaller than the second band gap.

### TECHNICAL FIELD

Embodiments of the present invention relate to a transistor, a semiconductor device, and a method for driving the semiconductor device. Another embodiment of the present invention relates to an electronic device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

In this specification and the like, a semiconductor device refers to every device that can function by utilizing semiconductor characteristics. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

### BACKGROUND ART

A technique by which a transistor is formed using a semiconductor thin film has been attracting attention. The transistor is used in a wide range of electronic devices such as an integrated circuit (IC) and an image display device (also simply referred to as a display device). Silicon-based semiconductor materials are widely known as materials for semiconductor thin films that can be used for transistors. As other materials, oxide semiconductors have been attracting attention.

For example, techniques have been disclosed by each of which a display device is manufactured using a transistor whose active layer is formed of zinc oxide or an In—Ga—Zn-based oxide as an oxide semiconductor (see Patent Documents 1 and 2).

In recent years, a technique has been disclosed by which an integrated circuit of a memory device is manufactured using a transistor including an oxide semiconductor (see Patent Document 3). Furthermore, not only memory devices but also arithmetic devices and the like are manufactured using transistors including oxide semiconductors

However, it is known that a transistor including an oxide semiconductor in a channel region has a problem in that the electrical characteristics are likely to be changed by impurities and oxygen vacancies in the oxide semiconductor and thus the reliability is low. For example, the threshold voltage of the transistor might be changed after a bias-temperature stress test (BT test).

### REFERENCE

[Patent Document 1] Japanese Published Patent Application No, 2007-123861
[Patent Document 2] Japanese Published Patent Application No, 2007-096055
[Patent Document 3] Japanese Published Patent Application No, 2011-119674

### DISCLOSURE OF INVENTION

An object of one embodiment of the present invention is to provide a semiconductor device having favorable electrical characteristics. Another object of one embodiment of the present invention is to provide a semiconductor device that can be miniaturized or highly integrated. Another object of one embodiment of the present invention is to provide a semiconductor device that can be manufactured with high productivity,

Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a semiconductor device with high design flexibility. Another object of one embodiment of the present invention is to provide a low-power semiconductor device. Another object of one embodiment of the present invention is to provide a novel semiconductor device.

Note that the description of these objects does not disturb the existence of other objects. In one embodiment of the present invention, there is no need to achieve all the objects. Other objects will be apparent from and can be derived from the description of the specification, the drawings, the claims, and the like,

In one embodiment of the present invention, a layer where a channel is formed (channel formation layer) has a structure in which thin layers having different band gaps are alternately stacked. In other words, in one embodiment of the present invention, a channel formation layer has a multilayer structure in which thin layers having different band gaps are alternately stacked.

The multilayer structure may be a structure like a superlattice structure. With the structure, a transistor can have high performance. Details thereof will be described below.

One embodiment of the present invention is a transistor comprising a gate electrode, a first conductor, a second conductor, a gate insulator, and a metal oxide. The gate insulator is located between the gate electrode and the metal oxide. The gate electrode includes a region overlapping with the metal oxide with the gate insulator therebetween. The first conductor and the second conductor each include a region in contact with top and side surfaces of the metal oxide. The metal oxide has a layered structure in which oxides (oxide layers) each having a first band gap and oxides (oxide layers) each having a second band gap and being adjacent to the oxide having the first band gap are alternately stacked in a thickness direction. The metal oxide includes two or more oxides each having the first band gap. The first band gap is smaller than the second band gap. A difference between the second band gap and the first band gap is greater than or equal to 0.1 eV and less than or equal to 2.5 eV or greater than or equal to 0.3 eV and less than or equal to 1.3 eV

Another embodiment of the present invention is a transistor comprising a gate electrode, a first conductor, a second conductor, a gate insulator, and a metal oxide. The gate insulator is located between the gate electrode and the metal oxide. The gate electrode includes a region overlapping with the metal oxide with the gate insulator therebetween. The first conductor and the second conductor each include a region in contact with top and side surfaces of the metal oxide. The metal oxide has a layered structure in which oxides each having a first band gap and oxides each having a second band gap and being adjacent to the oxide having the first band gap are alternately stacked in a thickness direction. The metal oxide includes two or more oxides each having the first band gap. The first band gap is smaller than the second band gap. A difference in the conduction band minimum between the oxide having the second band gap and the oxide having the first band gap is greater than or equal to 0.3 eV and less than or equal to 1.3 eV.

Another embodiment of the present invention is a transistor comprising a gate electrode, a first conductor, a second conductor, a gate insulator, and a metal oxide. The gate insulator is located between the gate electrode and the metal oxide. The gate electrode includes a region overlapping with the metal oxide with the gate insulator therebetween. The first conductor and the second conductor each include a region in contact with top and side surfaces of the metal oxide. The metal oxide has a layered structure in which oxides each having a first band gap and oxides each having a second band gap and being adjacent to the oxide having the first band gap are alternately stacked in a thickness direction. The metal oxide includes two or more oxides each having the first band gap. The first band gap is smaller than the second band gap. The oxides each having the first band gap include either or both of indium and zinc. The oxides each having the second hand gap include either or both of indium and zinc and an element M.

The element M is one or more of aluminum, gallium, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like.

Another embodiment of the present invention is a transistor comprising a gate electrode, a first conductor, a second conductor, a gate insulator, and a metal oxide. The gate insulator is located between the gate electrode and the metal oxide. The gate electrode includes a region overlapping with the metal oxide with the gate insulator therebetween. The first conductor and the second conductor each include a region in contact with top and side surfaces of the metal oxide. The metal oxide has a layered structure in which oxides each having a first band gap and oxides each having a second band gap and being adjacent to the oxide having the first band gap are alternately stacked in a thickness direction. The metal oxide includes two or more oxides each having the first band gap. The first band gap is smaller than the second band gap. The oxides each having the first band gap include either or both of indium and zinc and an element The element M is one or more of aluminum, gallium, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like. The oxides each having the second hand gap include either or both of indium and zinc and the element M. The oxides each having the second band gap include more elements M than the oxides each having the first band gap,

Another embodiment of the present invention is a transistor comprising a gate electrode, a first conductor, a second conductor, a gate insulator, a first metal oxide, a second metal oxide, and a third metal oxide. The gate insulator is located between the gate electrode and the first metal oxide. The gate electrode includes a region overlapping with the second metal oxide with the gate insulator and the first metal oxide therebetween. The first conductor and the second conductor each include a region in contact with top and side surfaces of the second metal oxide. The second metal oxide includes a region in contact with a top surface of the third metal oxide. The second metal oxide has a layered structure in which oxides each having a first band gap and oxides each having a second band gap being adjacent to the oxides the first band gap are alternately stacked in a thickness direction. The second metal oxide includes two or more oxides each having the first band gap. The first band gap is smaller than the second band gap. A difference between the second band gap and the first band gap is greater than or equal to 0.1 eV and less than or equal to 2.5 eV or greater than or equal to 0.3 eV and less than or equal to 1.3 eV.

In the above embodiment, the second metal oxide includes a channel formation region. The first metal oxide preferably extends in a channel width direction of the channel formation region so as to cover the second metal oxide.

In the above embodiment, the number of the oxides each having the first band gap in the second metal oxide is preferably three or more and ten or less.

In the above embodiment, the band gaps of the first metal oxide and the third metal oxide are each preferably larger than the band gap of the second metal oxide.

In the above embodiment, a thickness of the oxide having the first band gap is preferably greater than or equal to 0.5 nm and less than or equal to 10 nm.

In the above embodiment, a thickness of the oxide having the first band gap is preferably greater than or equal to0.5 nm and less than or equal to 2.0 nm.

In the above embodiment, a thickness of the oxide having the second hand gap is preferably greater than or equal to 0.1 nm and less than or equal to 10 nm.

In the above embodiment, a thickness of the oxide having the second band gap is preferably greater than or equal to 0.1 nm and less than or equal to 3.0 nm,

In the above embodiment, a distance between an edge of the first conductor and an edge of the second conductor is preferably greater than or equal to 10 nm and less than or equal to 300 nm.

In the above embodiment, a width of the gate electrode is preferably greater than or equal to 10 nm and less than or equal to 300 nm.

In the above embodiment, a carrier density in the oxide having the first band gap is preferably greater than or equal to 6×10¹⁸ cm ⁻³ and less than or equal to 5×10²⁰ cm⁻³.

In the above embodiment, the oxide having the first band gap is preferably degenerate.

In the above embodiment, the oxide having the first band gap preferably includes either or both of indium and zinc.

In the above embodiment, the oxide having the first band gap preferably includes either or both of indium and zinc and the element M.

In the above embodiment, the oxide having the second band gap preferably includes indium, zinc, and the element M.

In the above embodiment, the oxide having the first band gap preferably includes more hydrogen than the oxide having the second band gap.

In the above embodiment, a hydrogen concentration in the oxide having the first band gap is preferably greater than 1×10¹⁹ cm⁻³.

In the above embodiment, the number of the oxides each having the first band gap in the metal oxide is preferably three or more and ten or less.

One embodiment of the present invention can provide a semiconductor device having favorable electrical characteristics. Another embodiment of the present invention can provide a semiconductor device that can be miniaturized or highly integrated. Another embodiment of the present invention can provide a semiconductor device that can be manufactured with high productivity.

Another embodiment of the present invention can provide a semiconductor device capable of retaining data for a long time. Another embodiment of the present invention can provide a semiconductor device capable of high-speed data writing. Another embodiment of the present invention can provide a semiconductor device with high design flexibility. Another embodiment of the present invention can provide a low-power semiconductor device. Another embodiment of the present invention can provide a novel semiconductor device.

Note that the description of these effects does not preclude the existence of other effects. One embodiment of the present invention does not have to have all the effects listed above. Other effects will be apparent from and can be derived from the description of the specification, the drawings, the claims, and the like.

### BRIEF DESCRIPTION OF DRAWINGS

FIGS. 1A to 1C are a top view and cross-sectional views illustrating the structure of a transistor of one embodiment of the present invention.

FIGS. 2A to 2C are a top view and cross-sectional views illustrating the structure of a transistor of one embodiment of the present invention.

FIGS. 3A and 3B are cross-sectional views illustrating the structure of a transistor of one embodiment of the present invention.

FIGS. 4A and 4B are cross-sectional views illustrating the structure of a transistor of one embodiment of the present invention.

FIGS. 5A and 5B are cross-sectional views illustrating the structure of a transistor of one embodiment of the present invention.

FIGS. 6A to 6C are a top view and cross-sectional views illustrating the structure of a transistor of one embodiment of the present invention.

FIGS. 7A to 7C are a top view and cross-sectional views illustrating a method for manufacturing a transistor of one embodiment of the present invention.

FIGS. 8A to 8C are a top view and cross-sectional views illustrating the method for manufacturing a transistor of one embodiment of the present invention.

FIGS. 9A to 9C are a top view and cross-sectional views illustrating the method for manufacturing a transistor of one embodiment of the present invention.

FIGS. 10A to 10C are a top view and cross-sectional views illustrating the method for manufacturing a transistor of one embodiment of the present invention.

FIG. 11 is a schematic view illustrating a deposition chamber of a sputtering apparatus.

FIG. 12 shows the band structure of an oxide.

FIGS. 13A and 13B are each a band diagram of the layered structure of an oxide of one embodiment of the present invention.

FIGS. 14A and 14B are each a band diagram of the layered structure of an oxide of one embodiment of the present invention.

FIGS. 15A and 15B are each a band diagram of the layered structure of an oxide of one embodiment of the present invention.

FIGS. 16A and 16B are each a band diagram of the layered structure of an oxide of one embodiment of the present invention.

FIGS. 17A to 17C are a top view and cross-sectional views illustrating the structure of a transistor of one embodiment of the present invention.

FIGS. 18A to 18C are a top view and cross-sectional views illustrating the structure of a transistor of one embodiment of the present invention.

FIG. 19 is a cross-sectional view of a semiconductor device of one embodiment of the present invention.

FIG. 20 is a cross-sectional view of a semiconductor device of one embodiment of the present invention.

### BEST MODE FOR CARRYING OUT THE INVENTION

Hereinafter, embodiments will be described with reference to drawings. Note that the embodiments can he implemented with various modes, and it will be readily appreciated by those skilled in the art that modes and details can be changed in various ways without departing from the spirit and scope of the present invention. Thus, the present invention should not be interpreted as being limited to the following description of the embodiment.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to the shapes or values shown in the drawings. In the drawings, the same portions or portions having similar functions are denoted by the same reference numerals in different drawings, and explanation thereof will not be repeated. In addition, the same hatching pattern is applied to portions having similar functions, and the portions are not particularly denoted by reference numerals in some cases.

Note that the ordinal numbers such as “first” and “second” in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

In this specification, terms for describing arrangement, such as “over”, “above”, “under”, and “below”, are used for convenience in describing a positional relation between components with reference to drawings. Furthermore, the positional relation between components is changed as appropriate in accordance with the direction in which each component is described. Thus, there is no limitation on terms used in this specification, and description can be made appropriately depending on the situation.

The “semiconductor device” in this specification and the like means every device which can operate by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic device may each include a semiconductor device.

In this specification and the like, a transistor is an element having at least three terminals of a gate, a drain, and a source. The transistor has a channel formation region between a drain (a drain terminal, a drain region, or a drain electrode) and a source (a source terminal, a source region, or a source electrode), and current can flow between the source and the drain via the channel formation region. Note that in this specification and the like, a channel region refers to a region through which current mainly flows.

Furthermore, the functions of a source and a drain might be interchanged with each other when transistors having different polarities are employed or the direction of current flow is changed in circuit operation, for example. Therefore, the terms “source” and “drain” can be interchanged with each other in this specification and the like.

Note that in this specification and the like, a silicon oxynitride film refers to a film in which the proportion of oxygen is higher than that of nitrogen. The silicon oxynitride film preferably contains oxygen, nitrogen, silicon, and hydrogen at concentrations ranging from 55 atomic % to 65 atomic %, 1 atomic % to 20 atomic %, 25 atomic % to 35 atomic %, and 0.1 atomic % to 10 atomic %, respectively. A silicon nitride oxide film refers to a film in which the proportion of nitrogen is higher than that of oxygen. The silicon nitride oxide film preferably contains nitrogen, oxygen, silicon, and hydrogen at concentration ranging from 55 atomic % to 65 atomic %, 1 atomic % to 20 atomic %, 25 atomic % to 35 atomic %, and 0.1 atomic % to 10 atomic %, respectively.

In this specification and the like, the terms “film” and “layer” can be interchanged with each other. For example, the term “conductive layer” can be changed into the term “conductive film” in some cases. Also, the term “insulating film” can be changed into the term “insulating layer” in some cases.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. In addition, the term “substantially perpendicular” indicates that the angle formed between two straight lines is greater than or equal to 60° and less than or equal to 120°.

In this specification, trigonal and rhombohedral crystal systems are included in a hexagonal crystal system.

For example, in this specification and the like, an explicit description “X and Y are connected” means that X and Y are electrically connected, X and Y are functionally connected, and X and Y are directly connected. Accordingly, without being limited to a predetermined connection relation, for example, the connection relation shown in drawings or texts, another connection relation is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y provided therebetween.

For example, in the case where X and Y are electrically connected, one or more elements that enable an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit and a step-down circuit) and a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; and a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, and a layer),

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

Note that in this specification, a barrier film refers to a film having a function of inhibiting the passage of oxygen and impurities such as hydrogen. The barrier film that has conductivity may be referred to as a conductive barrier film.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. That is to say, a metal oxide that has at least one of an amplifying function, a rectifying function, and a switching function can be called a metal oxide semiconductor, or OS for short. In addition, an OS FET is a transistor including a metal oxide or an oxide semiconductor.

In this specification and the like, “c-axis aligned crystal (CAAC)” or “cloud-aligned composite (CAC)” may be stated. CAAC refers to an example of a crystal structure, and CAC refers to an example of a function or material composition.

Note that CAC-OS or CAC-metal oxide may he called a matrix composite or a metal matrix composite. Thus. CAC-OS may be called a cloud-aligned composite OS.

In this specification and the like. CAC-OS or CAC-metal oxide has a function of a conductor in a part of the material and has a function of a dielectric (or insulator) in another part of the material; as a whole. CAC-OS or CAC-metal oxide has a function of a semiconductor. In the case where CAC-OS or CAC-metal oxide is used in a semiconductor layer of a transistor, the conductor regions have a function of letting electrons (or holes) serving as carriers flow, and the dielectric regions have a function of not letting electrons serving as carriers flow. By the complementary action of the function as a conductor and the function as a dielectric. CAC-OS or CAC-metal oxide can have a switching function (on/off function). In the CAC-OS or CAC-metal oxide, separation of the functions can maximize each function.

In this specification and the like. CAC-OS or CAC-metal oxide includes conductor regions and dielectric regions. The conductor regions have the above-described function of the conductor, and the dielectric regions have the above-described function of the dielectric. In some cases, the conductor regions and the dielectric regions in the material are separated at the nanoparticle level. In some cases, the conductor regions and the dielectric regions are unevenly distributed in the material. When observed, the conductor regions are coupled in a cloud-like manner with their boundaries blurred, in some cases.

In other words. CAC-OS or CAC-metal oxide can be called a matrix composite or a metal matrix composite.

Furthermore, in the CAC-OS or CAC-metal oxide, each of the conductor regions and the dielectric regions has a size of more than or equal to 0.5 nm and less than or equal to 10 nm, preferably more than or equal to 0.5 nm and less than or equal to 3 nm and is dispersed in the material, in some cases.

### Embodiment 1

### <Transistor Structure 1>

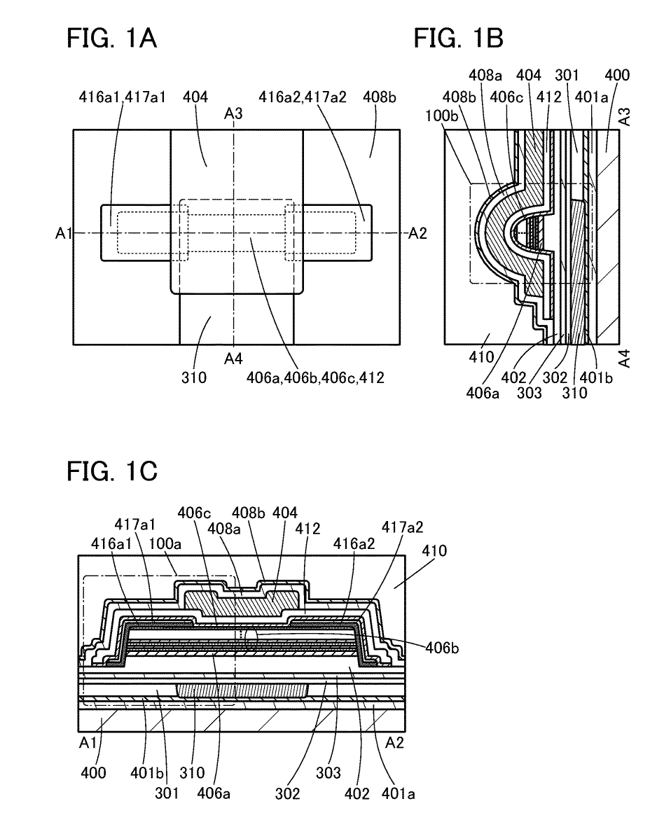

FIG. 1A is a top view of a transistor of one embodiment of the present invention. FIG. 1B is a cross-sectional view taken along the dashed-dotted line A3-A4 in FIG. 1A, or a cross-sectional view in the channel width direction of a channel formation region of the transistor. FIG. 1C is a cross-sectional view taken along the dashed-dotted line A1-A2 in FIG. 1A, or a cross-sectional view in the channel length direction of the transistor. Some components in the top view in FIG. 1A are not illustrated for simplification of the drawing.

In FIGS. 1B and 1C, the transistor is provided over an insulator 401a and an insulator 401b over a substrate 400. The transistor includes a conductor 310 and an insulator 301 over the insulator 401b: an insulator 302 over the conductor 310 and the insulator 301: an insulator 303 over the insulator 302; an insulator 402 over the insulator 303; an oxide 406a over the insulator 402; an oxide 406b over the oxide 406a; a conductor 416a1 and a conductor 416a2 each including a region in contact with the top and side surfaces of the oxide 406b; an oxide 406c including a region in contact with the side surface of the conductor 416a1, the side surface of the conductor 416a2, and the top surface of the oxide 406b; an insulator 412 over the oxide 406c; and a conductor 404 including a region overlapping with the oxide 406c with the insulator 412 therebetween. The insulator 301 has an opening, and the conductor 310 is provided in the opening.

Furthermore, a barrier film 417a1, a barrier film 417a2, an insulator 408a, an insulator 408b, and an insulator 410 are provided over the transistor.

Note that a metal oxide can be used for the oxides 406a, 406b, and 406c.

In the transistor, the conductor 404 functions as a first gate electrode. Furthermore, the conductor 404 can have a layered structure including a conductor that has a function of inhibiting the passage of oxygen. For example, when a conductor that has a function of inhibiting the passage of oxygen is formed as a lower layer of the conductor 404, an increase in the electric resistivity due to oxidation of the conductor 404 can be prevented. The insulator 412 functions as a first gate insulator.

The conductors 416a1 and 416a2 function as source and drain electrodes of the transistor. The conductors 416a1 and 416a2 can each have a layered structure including a conductor that has a function of inhibiting the passage of oxygen. For example, when a conductor that has a function of inhibiting the passage of oxygen is formed as un upper layer of each of the conductors 416a1 and 416a2, an increase in the electric resistivity due to oxidation of the conductors 416a1 and 416a2 can be prevented. Note that the electric resistivities of the conductors can be measured by a two-terminal method or the like.

The barrier films 417a1 and 417a2 each have a function of inhibiting the passage of oxygen and impurities such as hydrogen and water. The barrier film 417a1 is located over the conductor 416a1 and prevents the diffusion of oxygen into the conductor 416a1. The barrier film 417a2 is located over the conductor 416a2 and prevents the diffusion of oxygen into the conductor 416a2.

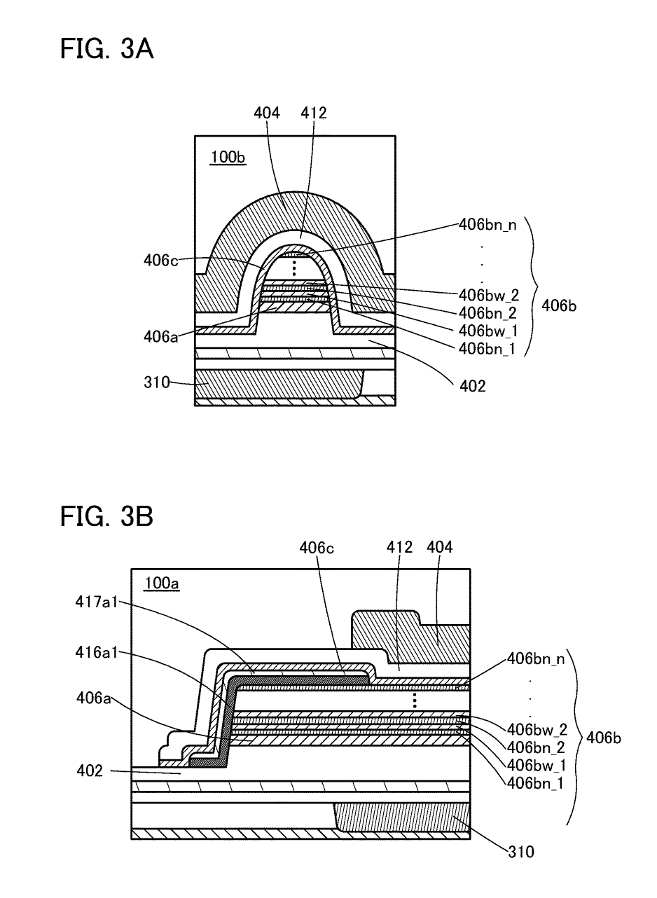

The structure of the oxide 406b will be described with reference to FIGS. 3A and 3B. FIG. 3A is an enlarged cross-sectional view illustrating a portion 100b surrounded by the dashed-dotted line in FIG. 1B. FIG. 3B is an enlarged cross-sectional view illustrating a portion 100a surrounded by the dashed-dotted line in FIG. 1C. Note that FIG. 3A is a cross-sectional view in the channel width direction of the transistor, and FIG. 3B is a cross-sectional view in the channel length direction of the transistor. Note that in FIGS. 3A and 3B, some components are not illustrated.

As illustrated in FIGS. 3A and 3B, the oxide 406b has a structure in which oxides 406bn each having a first band gap and oxides 406bw each having a second band gap are alternately stacked. The first band gap is smaller than the second band gap, and a difference between the first band gap and the second band gap is 0.1 eV to 2.5 eV inclusive or 0.3 eV to 1.3 eV inclusive. The carrier density of the oxide 406bn having the first band gap is higher than that of the oxide 406bw having the second band gap. A difference in the energy level of the conduction band minimum between the oxide 406bn having the first band gap and the oxide 406bw having the second band gap is 0.1 eV to 1.3 eV inclusive or 0.3 eV to 1.3 eV inclusive.

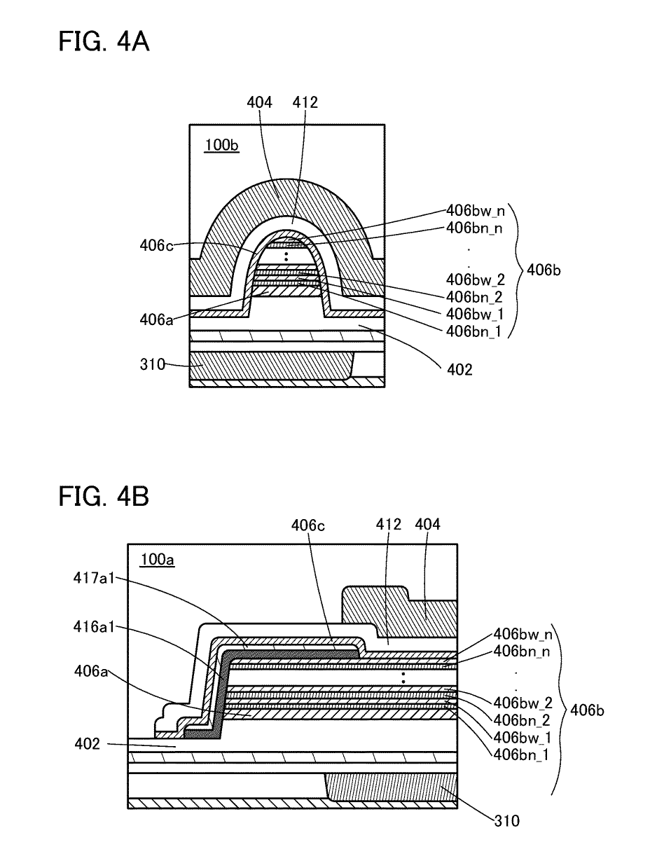

Specifically, an oxide 406bn_1 is provided in contact with the top surface of the oxide 406a, and an oxide 406bw_1 is provided in contact with the top surface of the oxide 406br_1. Similarly, an oxide 406bn_2 having the first band gap and an oxide 406bw_2 having the second band gap are stacked in this order, and an oxide 406bn_n having the first band gap is provided in the uppermost position of the oxide 406b. That is to say, the oxide 406b has a (2×n−1)-layer structure (n is a natural number). Alternatively, an oxide 406bw_n having the second band gap may be provided in the uppermost position of the oxide 406b. In that case, the oxide 406b has a (2×n)-layer structure (see FIGS. 4A and 4B). Note that the variable n is greater than or equal to 2, preferably greater than or equal to 3 and less than or equal to 10.

The oxide 406bn having the first band gap has a thickness of 0.1 nm to 5.0 nm inclusive, preferably 0.5 nm to 2.0 nm inclusive. The oxide 406bw having the second band gap has a thickness of 0.1 nm to 5.0 nm inclusive, preferably 0.1 nm to 3.0 nm inclusive.

As illustrated in FIG. 3A, the oxide 406c is provided so as to cover the whole oxide 406b. Furthermore, the conductor 404 functioning as a first gate electrode is provided so as to cover the whole oxide 406b with the insulator 412 functioning as a first gate insulator therebetween.

The distance between the edge of the conductor 416a1 and the edge of the conductor 416a2, or the channel length of the transistor is 10 nm to 300 nm inclusive, typically 20 nm to 180 nm inclusive. The conductor 404 functioning as a first gate electrode has a width of 10 nm to 300 nm inclusive, typically 20 nm to 180 nm inclusive.

The oxides 406a and 406c are each indium gallium zinc oxide or an oxide including an element M (the element M is one or more of Al, Ga, Si, B, Y, Ti, Fe, Ni, Ge, Zr, Mo, La, Ce, Nd, Hf, Ta, W, Mg, V, Be, and Cu); for example, gallium oxide or boron oxide can be used for the oxides 406a and 406c.

The oxide 406bn having the first band gap preferably includes indium, zinc, or the like. The oxide 406bn may include nitrogen. For example, indium oxide, indium zinc oxide, indium zinc oxide including nitrogen, indium zinc nitride, indium gallium zinc oxide including nitrogen, or the like can be used.

The oxide 406bw having the second band gap preferably includes gallium zinc oxide, indium gallium zinc oxide, or an element M (the element M is one or more of Al, Ga, Si, B, Y, Ti, Fe, Ni, Ge, Zr, Mo, La, Ce, Nd, Hf, Ta, W, Mg, V, Be, and Cu); for example, gallium oxide or boron oxide can be used for the oxide 406bw.

In the transistor, the resistance of the oxide 406b can be adjusted by controlling a potential supplied to the conductor 404 functioning as a first gate electrode. That is to say, conduction (the on state of the transistor) or non-conduction (the off state of the transistor) between the conductors 416a1 and 416a2 functioning as source and drain electrodes depends on a potential supplied to the conductor 404.

The conductors 416a1 and 416a2 functioning as source and drain electrodes are in contact with part of the top surface and parts of side surfaces of the oxide 406bn_n or the oxide 406bw_n in the uppermost layer of the oxide 406b. Parts of side surfaces of the layers other than the oxide 406bn_n or the oxide 406bw_n are in contact with the conductors 416a1 and 416a2. Thus, the conductor 416a1 and the conductor 416a2 functioning as source and drain electrodes are electrically connected to the layers of the oxide 406b.

The on state of the transistor in which the oxide 406b including the channel formation region has a structure where the oxides 406bn each having the first band gap and the oxides 406bw each having the second band gap are alternately stacked will be described.

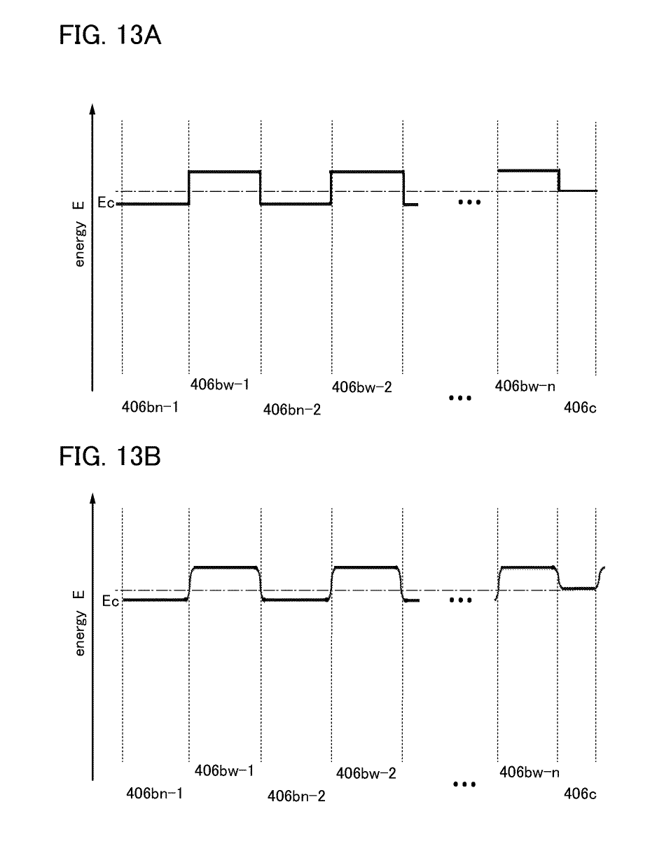

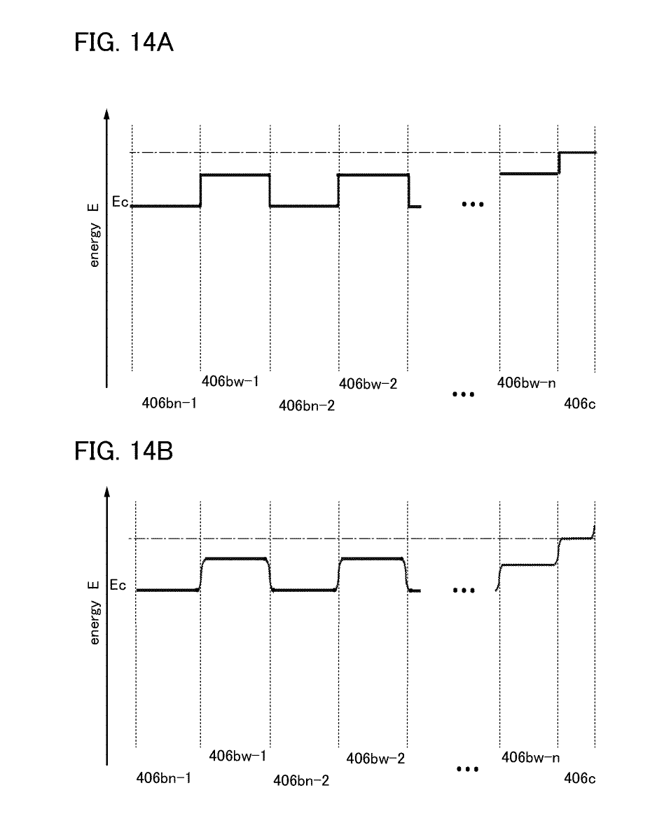

FIGS. 13A and 13B and FIGS. 14A and 14B are band diagrams of the vicinity of the conduction band minimum (hereinafter referred to as the Ec bottom) of the structure where the oxides 406bn each having the first band gap and the oxides 406bw each having the second hand gap are alternately stacked. FIGS. 13A and 13B each show an example where the band gap of the oxide 406c is larger than the first band gap and smaller than the second band gap. FIGS. 14A and 14B each show an example where the band gap of the oxide 406c is larger than the first band gap and the second hand gap.

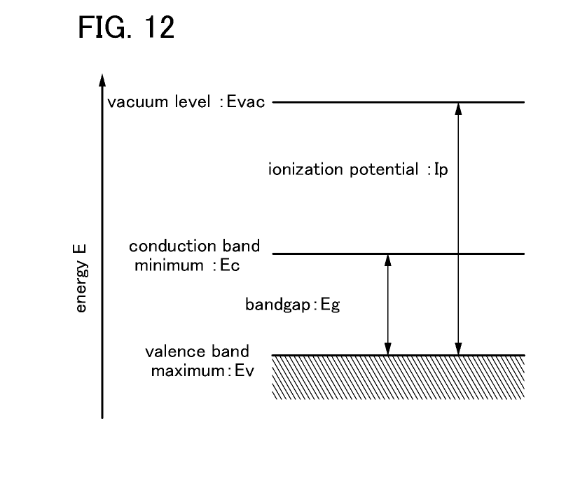

Here, measurement of the energy level of the Ec bottom of the oxide used for the transistor of one embodiment of the present invention will be described. FIG. 12 shows an example of the energy band of the oxide used for the transistor of one embodiment of the present invention. As shown in FIG. 12, the energy level of the Ec bottom can be calculated from an ionization potential Ip, which is a difference between the vacuum level and the energy level of the valence band maximum. Note that the band gap Eg can be measured using a spectroscopic ellipsometer (UT-300 manufactured by HORIBA JOBIN YVON S.A.S.). The ionization potential Ip can be measured using an ultraviolet photoelectron spectroscopy (UPS) apparatus (VersaProbe manufactured by Physical Electronics, Inc.).

As shown in FIG. 13A, the first band gap of the oxide 406bn is relatively narrow compared with the second band gap of the oxide 406bw; thus, the energy level of the Ec bottom of the oxide 406bn having the first band gap is relatively low compared with that of the oxide 406bw having the second band gap. The band gap of the oxide 406c is larger than the first band gap and smaller than the second band gap; thus, the energy level of the Ec bottom of the oxide 406c is located between the energy level of the Ec bottom of the oxide 406bn having the first band gap and the energy level of the Ec bottom of the oxide 406bw having the second band gap. In FIG. 14A, the band gap of the oxide 406c is larger than the first band gap and the second band gap; thus, the energy level of the Ec bottom of the oxide 406c is relatively high compared with the energy level of the Ec bottom of the oxide 406bw having the second band gap.

In a junction portion of the oxide 406bn having the first band gap and the oxide 406bw having the second band gap in an actual layered structure, the cohesion state of oxide and the composition might be non-uniform or part of the oxide 406bw having the second band gap might be included in the oxide 406bn having the first band gap. Accordingly, the energy level of the Ec bottom is not discontinuous and varies gradually as shown in FIG. 13B and FIG. 14B.

In the transistor having such a layered structure in the channel formation region, the oxides 406bn each having the first band gap and the oxides 406bw each having the second band gap electrically interact with each other; thus, when a potential at which the transistor is turned on is supplied to the conductor 404 functioning as a first gate electrode, the oxide 406bn having the first band gap and a low energy level of the Ec bottom serves as a main conduction path and electrons flow therethrough, and electrons also flow through the oxide 406bw having the second band gap. This is because the energy level of the Ec bottom of the oxide 406bw having the second band gap becomes significantly lower than that of the oxide 406bn having the first band gap. Thus, high current drive capability, or a large current and high field-effect mobility can be achieved in the transistor that is on.

As the oxide 406bn having the first band gap, for example, a metal oxide including indium zinc oxide as its main component and having high mobility is preferably used. The carrier density is higher than or equal to 6×10¹⁸ cm⁻³ and lower than or equal to 5×10²⁰ cm⁻³. The oxide 406bn may be degenerate.

As the oxide 406bw having the second band gap, an oxide including gallium oxide, gallium zinc oxide, or the like is preferably used.

When a voltage lower than the threshold voltage is applied to the conductor 404 functioning as a first gate electrode, the oxide 406bw having the second band gap behaves as a dielectric (an oxide having an insulating property), resulting in blockage of a conduction path in the oxide 406bw. The top and bottom surfaces of the oxide 406bn having the first band gap are in contact with the oxides 406bw each having the second band gap. The oxides 406bw each having the second band gap electrically interact with the oxides 406bn each having the first band gap, so that even the conduction path in the oxides 406bn each having the first band gap is also blocked. This is because the energy level of the Ec bottom of the oxide 406bw having the second band gap becomes significantly higher than that of the oxide 406bn having the first band gap. Consequently, the whole oxide 406b becomes in a non-conduction state, and the transistor is turned off.

As illustrated in FIG. 1C, the top and side surfaces of the oxide 406b include regions in contact with the conductor 416a1 and the conductor 416a2. As illustrated in FIG. 3A, the oxide 406c is provided so as to cover the whole oxide 406b. Furthermore, the conductor 404 functioning as a first gate electrode is provided so as to cover the whole oxide 406b with the insulator 412 functioning as a first gate insulator therebetween. Thus, the whole oxide 406b can be electrically surrounded by an electric field of the conductor 404 functioning as a first gate electrode. Such a transistor structure in which the channel formation region is electrically surrounded by the electric field of the first gate electrode is referred to as a surrounded channel (s-channel) structure. A channel can be formed in all the oxides 406bn each having the first band gap in the oxide 406b; thus, the above structure enables a large current flow between the source and the drain and an increase in current in an on state (on-state current). Since all the oxides 406bw each having the second band gap in the oxide 406b are surrounded by an electric field of the conductor 404, the above structure also allows a decrease in current in an off state (off-state current).

In the transistor, the conductor 404 functioning as a first gate electrode partly overlaps with each of the conductors 416a1 and 416a2 functioning as source and drain electrodes, whereby parasitic capacitance between the conductor 404 and the conductor 416a1 and parasitic capacitance between the conductor 404 and the conductor 416a2 are formed.

The transistor structure including the barrier flint 417a1 as well as the insulator 412 and the oxide 406c between the conductor 404 and the conductor 416a1 allows a reduction in the parasitic capacitance. Similarly, the transistor structure includes the barrier film 417a2 as well as the insulator 412 and the oxide 406c between the conductor 404 and the conductor 416a2, thereby allowing a reduction in the parasitic capacitance. Thus, the transistor has excellent frequency characteristics.

Furthermore, the above structure of the transistor allows reduction or prevention of generation of a leakage current between the conductor 404 and each of the conductor 416a1 and the conductor 416a2 when the transistor operates, for example, when a potential difference between the conductor 404 and each of the conductor 416a1 and the conductor 416a2 occurs.

The conductor 310 functions as a second gate electrode. The conductor 310 can be a multilayer film including a conductor that has a function of inhibiting the passage of oxygen. The use of the multilayer film including a conductor that has a function of inhibiting the passage of oxygen can prevent a decrease in conductivity due to oxidation of the conductor 310.

The insulator 302, the insulator 303, and the insulator 402 function as a second gate insulating film. By controlling a potential supplied to the conductor 310, the threshold voltage of the transistor can be adjusted.

### <Substrate>

As the substrate 400, for example, an insulator substrate, a semiconductor substrate, or a conductor substrate may be used. As the insulator substrate, for example, a glass substrate, a quartz substrate, a sapphire substrate, a stabilized zirconia substrate (e.g., an yttria-stabilized zirconia substrate), or a resin substrate is used. As the semiconductor substrate, for example, a single material semiconductor substrate made of silicon, germanium, or the like, a compound semiconductor substrate made of silicon carbide, silicon germanium, gallium arsenide, indium phosphide, zinc oxide, or gallium oxide, or the like is used. The above semiconductor substrate in which an insulator region is provided, e.g., a silicon on insulator (SOI) substrate may also be used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like may also be used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The substrate 400 includes a region with a thickness of, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device including the transistor can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, for example, metal, an alloy, resin, glass, or fiber thereof can be used. The flexible substrate 400 preferably has a lower coefficient of linear expansion because deformation due to an environment is suppressed. The flexible substrate 400 is formed using, for example, a material whose coefficient of linear expansion is lower than or equal to ×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

### <Insulator>

Note that when the transistor is surrounded by an insulator that has a function of inhibiting the passage of oxygen and impurities such as hydrogen, the electrical characteristics of the transistor can be stabilized. For example, an insulator that has a function of inhibiting the passage of oxygen and impurities such as hydrogen is used for the insulator 401a, the insulator 401b, the insulator 408a, and the insulator 408b.

The insulator that has a function of inhibiting the passage of oxygen and impurities such as hydrogen can have, for example, a single-layer structure or a layered structure including an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum.

Furthermore, for example, the insulator 401a, the insulator 401b, the insulator 408a, and the insulator 408b can be formed using a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride. Note that the insulator 401a, the insulator 401b, the insulator 408a, and the insulator 408b preferably include aluminum oxide.

For example, when the insulator 408a is formed using plasma containing oxygen, oxygen can be added to the insulator 412 serving as a base layer of the insulator 408a. The added oxygen serves as excess oxygen in the insulator 412, and is added to the oxide 406a, the oxide 406b, and the oxide 406c through the insulator 412 by heat treatment or the like, so that oxygen defects in the oxide 406a, the oxide 406b, and the oxide 406c can be repaired.

When the insulator 401a, the insulator 401b, the insulator 408a, and the insulator 408b include aluminum oxide, entry of impurities such as hydrogen into the oxide 406a, the oxide 406b, and the oxide 406c can be inhibited. Furthermore, outward diffusion of excess oxygen added to the oxide 406a, the oxide 406b, and the oxide 406c can be inhibited.

The insulator 301, the insulator 302, the insulator 303, the insulator 402, and the insulator 412 can each be formed to have, for example, a single-layer structure or a layered structure including an insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. For example, the insulator 301, the insulator 302, the insulator 303, the insulator 402, and the insulator 412 preferably include silicon oxide or silicon oxynitride.

Note that the insulator 302, the insulator 303, the insulator 402, and the insulator 412 preferably include an insulator with a high dielectric constant. For example, the insulator 302, the insulator 303, the insulator 402, and the insulator 412 preferably include gallium oxide, hafnium oxide, an oxide including aluminum and hafnium, an oxynitride including aluminum and hafnium, an oxide including silicon and hafnium, an oxynitride including silicon and hafnium, or the like. Alternatively, the insulator 302, the insulator 303, the insulator 402, and the insulator 412 each preferably have a layered structure of silicon oxide or silicon oxynitride and an insulator with a high dielectric constant. Because silicon oxide and silicon oxynitride have thermal stability, combination of silicon oxide or silicon oxynitride with an insulator with a high dielectric constant allows the layered structure to be thermally stable and have a high dielectric constant. For example, when aluminum oxide, gallium oxide, or hafnium oxide is positioned on the oxide 406c side, entry of silicon included in the silicon oxide or the silicon oxynitride into the oxide 406b can be inhibited. When silicon oxide or silicon oxynitride is positioned on the oxide 406c side, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases.

The insulator 410 preferably includes an insulator with a low dielectric constant. For example, the insulator 410 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator 410 preferably has a layered structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the layered structure can have thermal stability and a low dielectric constant. Examples of the resin include polyester, polyolefin, polyamide (e.g., nylon or aramid), polyimide, polycarbonate, and acrylic.

The barrier films 417a1 and 417a2 can be formed using an insulator that has a function of inhibiting the passage of oxygen and impurities such as hydrogen and water. The barrier films 417a1 and 417a2 can prevent excess oxygen in the insulator 410 from diffusing into the conductors 416a1 and 416a2.

The barrier films 417a1 and 417a2 can be formed using a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; or silicon nitride, for example. Note that the barrier films 417a1 and 417a2 preferably include aluminum oxide.

### <Conductor>

The conductor 404, the conductor 310, the conductor 416a1, and the conductor 416a2 can be formed using a material including one or more metal elements selected from aluminum, chromium, copper, silver, gold, platinum, tantalum, nickel, titanium, molybdenum, tungsten, hafnium, vanadium, niobium, manganese, magnesium, zirconium, beryllium, indium, and the like. Alternatively, a semiconductor having high electric conductivity typified by polycrystalline silicon including an impurity element such as phosphorus, or silicide such as nickel silicide may be used.

Alternatively, a conductive material including oxygen and any of the metal elements listed above or a conductive material including nitrogen and any of the metal elements listed above may be used. For example, a conductive material including nitrogen, such as titanium nitride or tantalum nitride may be used. Alternatively, indium tin oxide (ITO), indium oxide including tungsten oxide, indium zinc oxide including tungsten oxide, indium oxide including titanium oxide, indium tin oxide including titanium oxide, indium zinc oxide, indium tin oxide to which silicon is added, or indium gallium zinc oxide including nitrogen may be used.

A stack of a plurality of conductive layers formed using any of the above materials may be used. For example, a layered structure formed using a combination of a material including any of the metal elements listed above and a conductive material including oxygen may be used. Alternatively, a layered structure formed using a combination of a material including any of the metal elements listed above and a conductive material including nitrogen may be used. Alternatively, a layered structure formed using a combination of a material including any of the metal elements listed above, a conductive material including oxygen, and a conductive material including nitrogen may be used.

Note that in the case where an oxide is used in the channel formation region of the transistor, a layered structure formed using a combination of a material including any of the metal elements listed above and a conductive material including oxygen is preferably used for the gate electrode. In that case, the conductive material including oxygen is preferably provided on the channel formation region side so that oxygen released from the conductive material is easily supplied to the channel formation region.

### <Transistor Structure 2>

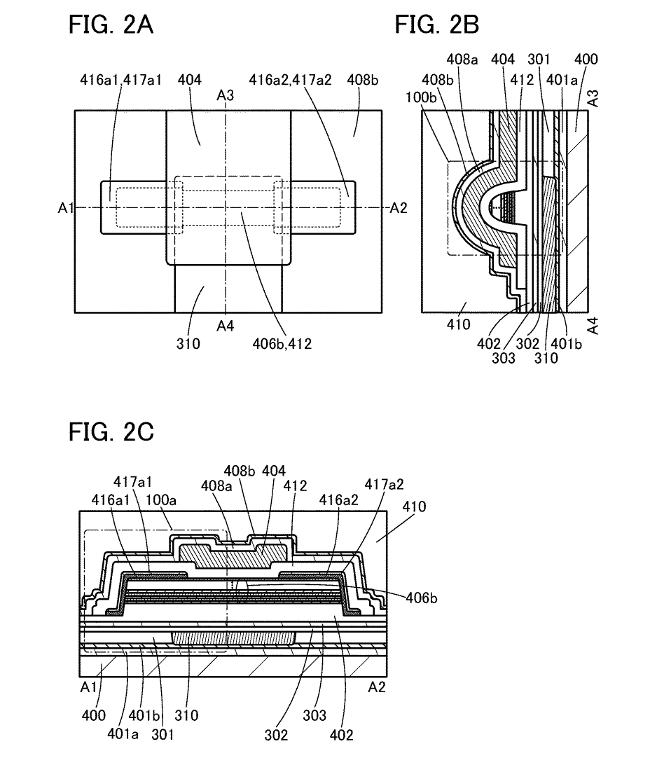

FIGS. 2A to 2C illustrate a transistor having a structure different from that in FIGS. 1A to 1C. FIG. 2A is a top view of a transistor of one embodiment of the present invention. FIG. 2B is a cross-sectional view taken along the dashed-dotted line A3-A4 in FIG. 2A, or a cross-sectional view in the channel width direction of a channel formation region of the transistor. FIG. 2C is a cross-sectional view taken along the dashed-dotted line A1-A2 in FIG. 2A, or a cross-sectional view in the channel length direction of the transistor. Some components in the top view in FIG. 2A are not illustrated for simplification of the drawing.

The transistor structure 2 is different from the transistor structure 1 in not including the oxide 406a and the oxide 406c. In FIGS. 2B and 2C, the transistor is provided over the insulator 401a and the insulator 401b over the substrate 400. The transistor includes the conductor 310 and the insulator 301 over the insulator 401b; the insulator 302 over the conductor 310 and the insulator 301; the insulator 303 over the insulator 302; the insulator 402 over the insulator 303; the oxide 406b over the insulator 402; the conductor 416a1 and the conductor 416a2 each including a region in contact with the top and side surfaces of the oxide 406b; the insulator 412 including a region in contact with the side surface of the conductor 416a1, the side surface of the conductor 416a2, and the top surface of the oxide 406b; and the conductor 404 including a region overlapping with the oxide 406b with the insulator 412 therebetween. The insulator 301 has an opening, and the conductor 310 is provided in the opening.

Furthermore, the barrier film 417a1, the barrier film 417a2, the insulator 408a, the insulator 408b, and the insulator 410 are provided over the transistor.

Note that the oxide 406b can he formed using a metal oxide.

In the transistor, the conductor 404 functions as a first gate electrode. Furthermore, the conductor 404 can have a layered structure including a conductor that has a function of inhibiting the passage of oxygen. For example, when a conductor that has a function of inhibiting the passage of oxygen is formed as a lower layer of the conductor 404, an increase in the electric resistivity due to oxidation of the conductor 404 can be prevented. The insulator 412 functions as a first gate insulator.

The conductors 416a1 and 416a2 function as source and drain electrodes of the transistor. The conductors 416a1 and 416a2 can each have a layered structure including a conductor that has a function of inhibiting the passage of oxygen. For example, when a conductor that has a function of inhibiting the passage of oxygen is formed as un upper layer of each of the conductors 416a1 and 416a2, an increase in the electric resistivity due to oxidation of the conductors 416a1 and 416a2 can he prevented. Note that the electric resistivities of the conductors can be measured by a two-terminal method or the like.

The barrier films 417a1 and 417a2 each have a function of inhibiting the passage of oxygen and impurities such as hydrogen and water. The barrier film 417a1 is located over the conductor 416a1 and prevents the diffusion of oxygen into the conductor 416a1. The barrier film 417a2 is located over the conductor 416a2 and prevents the diffusion of oxygen into the conductor 416a2.

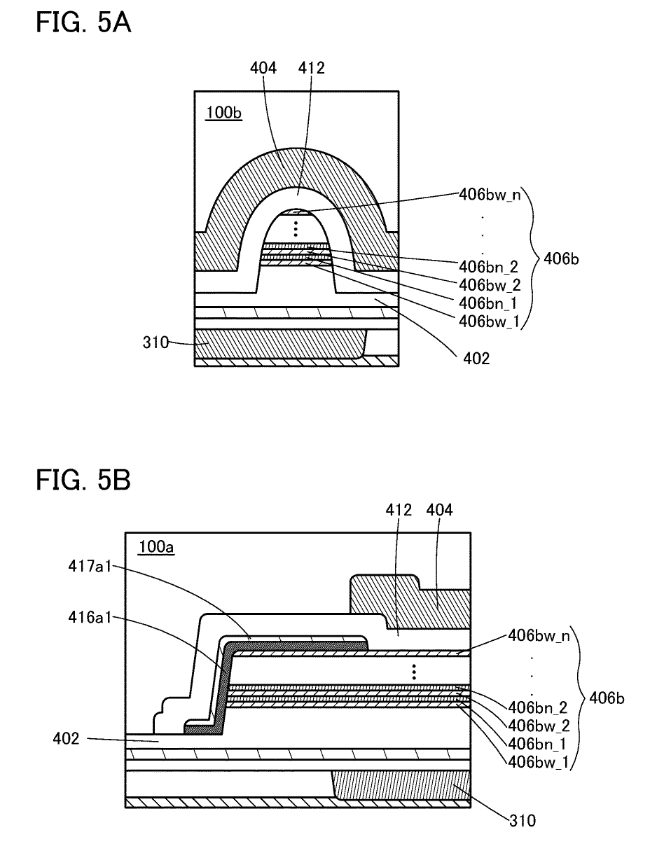

The structure of the oxide 406b will be described with reference to FIGS. 5A and 5B. FIG. 5A is an enlarged cross-sectional view illustrating a portion 100b surrounded by the dashed-dotted line in FIG. 2B. FIG. 5B is an enlarged cross-sectional view illustrating a portion 100a surrounded by the dashed-dotted line in FIG. 2C. Note that FIG. 5A is a cross-sectional view in the channel width direction of the transistor, and FIG. 5B is a cross-sectional view in the channel length direction of the transistor. Note that in FIGS. 5A and 5B, some components are not illustrated.

As illustrated in FIGS. 5A and 5B, the oxide 406b has a multilayer structure in which oxides 406bn each having a first band gap and oxides 406bw each having a second hand gap are alternately stacked. The first band gap is smaller than the second band gap, and a difference between the first band gap and the second hand gap is 0.1 eV to 2.5 eV inclusive or 0.3 eV to 1.3 eV inclusive. The carrier density of the oxide 406bn having the first band gap is higher than that of the oxide 406bw having the second band gap.

Specifically, the oxide 406bw_1 is provided in contact with the top surface of the insulator 402, and the oxide 406bn_1 is provided in contact with the top surface of the oxide 406bw_1. Similarly, the oxide 406bw_2 having the second band gap and the oxide 406bn_2 having the first band gap are stacked in this order, and the oxide 406bw_n having the second band gap is provided in the uppermost position of the oxide 406b. That is to say, the oxide 406b has a (2×n−1)-layer structure (n is a natural number). Alternatively, an oxide 406bn_n having the first band gap may be provided in the uppermost position of the oxide 406b. In that case, the oxide 406b has a (2×n)-layer structure. Note that the variable n is greater than or equal to 2, preferably greater than or equal to 3 and less than or equal to 10.

The oxide 406bn having the first band gap has a thickness of 0.1 nm to 5.0 nm inclusive, preferably 0.5 nm to 2.0 nm inclusive. The oxide 406bw having the second band gap has a thickness of 0.1 nm to 5.0 nm inclusive, preferably 0.1 nm to 3.0 nm inclusive.

As illustrated in FIG. 5A, the conductor 404 functioning as a first gate electrode is provided so as to cover the whole oxide 406b with the insulator 412 functioning as a first gate insulator therebetween.

The distance between the edge of the conductor 416a1 and the edge of the conductor 416a2, or the channel length of the transistor is 10 nm to 300 nm inclusive, typically 20 nm to 180 nm inclusive. The conductor 404 functioning as a first gate electrode has a width of 10 nm to 300 nm inclusive, typically 20 nm to 180 nm inclusive.

The oxide 406bn having the first band gap preferably includes indium, zinc, or the like. The oxide 406bn may include nitrogen. For example, indium oxide, indium zinc oxide, indium zinc oxide including nitrogen, indium zinc nitride, indium gallium zinc oxide including nitrogen, or the like can be used.

The oxide 406bw having the second band gap preferably includes gallium zinc oxide, indium gallium zinc oxide, or an element M (the element M is one or more of Al, Ga, Si, B, Y, Ti, Fe, Ni, Ge, Zr, Mo, La, Ce, Nd, Hf, Ta, W, Mg, V, Be, and Cu); for example, gallium oxide or boron oxide can be used for the oxide 406bw.

In the transistor, the resistance of the oxide 406b can be adjusted by controlling a potential supplied to the conductor 404 functioning as a first gate electrode. That is to say, conduction (the on state of the transistor) or non-conduction (the off state of the transistor) between the conductors 416a1 and 416a2 functioning as source and drain electrodes depends on a potential supplied to the conductor 404.

The conductors 416a1 and 416a2 functioning as source and drain electrodes are in contact with part of the top surface and parts of side surfaces of the oxide 406bw_n or the oxide 406bn_n in the uppermost layer of the oxide 406b. Parts of side surfaces of the layers other than the oxide 406bw_n or the oxide 406bn are in contact with the conductors 416a1 and 416a2. Thus, the conductor 416a1 and the conductor 416a2 functioning as source and drain electrodes are electrically connected to the layers of the oxide 406b.

The on state of the transistor in which the oxide 406b including the channel formation region has a structure where the oxides 406bn each having the first band gap and the oxides 406bw each having the second band gap are alternately stacked will be described.

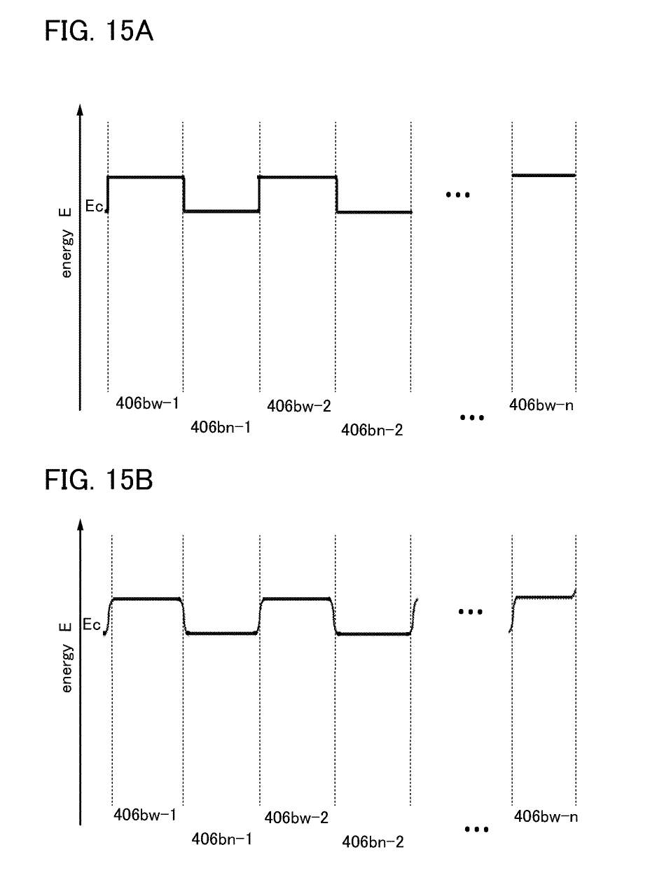

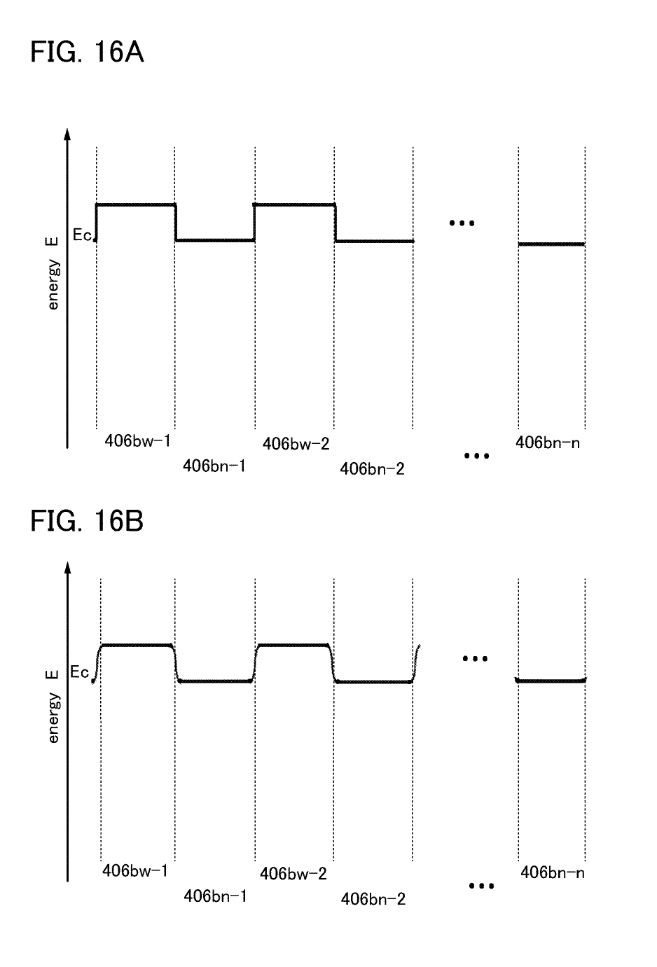

FIGS. 15A and 15B and FIGS. 16A and 16B are band diagrams of the vicinity of the Ec bottom of the structure where the oxides 406bn each having the first band gap and the oxides 406bw each having the second band gap are alternately stacked. FIGS. 15A and 15B are each a band diagram showing the case where the oxide 406bw_n having the second band gap is provided in the uppermost position of the oxide 406b. FIGS. 16A and 16B each are each a band diagram showing the case where the oxide 406bn_n having the first band gap is provided in the uppermost position of the oxide 406b.

In a junction portion of the oxide 406bn having the first band gap and the oxide 406bw having the second band gap in an actual layered structure, the cohesion state of oxide and the composition might be non-uniform or part of the oxide 406bw having the second band gap might be included in the oxide 406bn having the first band gap. Accordingly, the energy level of the Ec bottom is not discontinuous and varies gradually as shown in FIG. 15B and FIG. 16B.

In the transistor having such a layered structure in the channel formation region, the oxides 406bn each having the first band gap and the oxides 406bw each having the second band gap electrically interact with each other; thus, when a potential at which the transistor is turned on is supplied to the conductor 404 functioning as a first gate electrode, the oxide 406bn having the first band gap and a low energy level of the Ec bottom serves as a main conduction path and electrons flow therethrough, and electrons also flow through the oxide 406bw having the second band gap. This is because the energy level of the Ec bottom of the oxide 406bw having the second band gap becomes significantly lower than that of the oxide 406bn having the first band gap. Thus, high current drive capability, or a large current and high field-effect mobility can be achieved in the transistor that is on.

As the oxide 406bn having the first band gap, for example, a metal oxide including indium zinc oxide as its main component and having high mobility is preferably used. The carrier density is higher than or equal to 6×10¹⁸ cm⁻³ and lower than or equal to 5×10²⁰ cm⁻³. The oxide 406bn may be degenerate.

As the oxide 406bw having the second band gap, an oxide including gallium oxide, gallium zinc oxide, or the like is preferably used.

When a voltage lower than the threshold voltage is applied to the conductor 404 functioning as a first gate electrode, the oxide 406bw having the second hand gap behaves as a dielectric (an oxide having an insulating property), resulting in blockage of a conduction path in the oxide 406bw. The top and bottom surfaces of the oxide 406bn having the first band gap are in contact with the oxides 406bw each having the second band gap. The oxides 406bw each having the second band gap electrically interact with the oxides 406bn each having the first hand gap, so that even the conduction path in the oxides 406bn each having the first band gap is also blocked. This is because the energy level of the Ec bottom of the oxide 406bw having the second band gap becomes significantly higher than that of the oxide 406bn having the first band gap. Consequently, the whole oxide 406b becomes in a non-conduction state, and the transistor is turned off.

As illustrated in FIG. 2C, the top and side surfaces of the oxide 406b include regions in contact with the conductor 416a1 and the conductor 416a2. As illustrated in FIG. 5A, the conductor 404 functioning as a first gate electrode is provided so as to cover the whole oxide 406b with the insulator 412 functioning as a first gate insulator therebetween. Thus, the whole oxide 406b can be electrically surrounded by an electric field of the conductor 404 functioning as a first gate electrode. Such a transistor structure in which the channel formation region is electrically surrounded by the electric field of the first gate electrode is referred to as a surrounded channel (s-channel) structure. A channel can be formed in all the oxides 406bn each having the first band gap in the oxide 406b; thus, the above structure enables a large current flow between the source and the drain and an increase in current in an on state (on-state current). Since all the oxides 406bw each having the second hand gap in the oxide 406b are surrounded by an electric field of the conductor 404, the above structure also allows a decrease in current in an off state (off-state current).

For the other components and functions, refer to the transistor structure 1.

### <Transistor Structure 3>

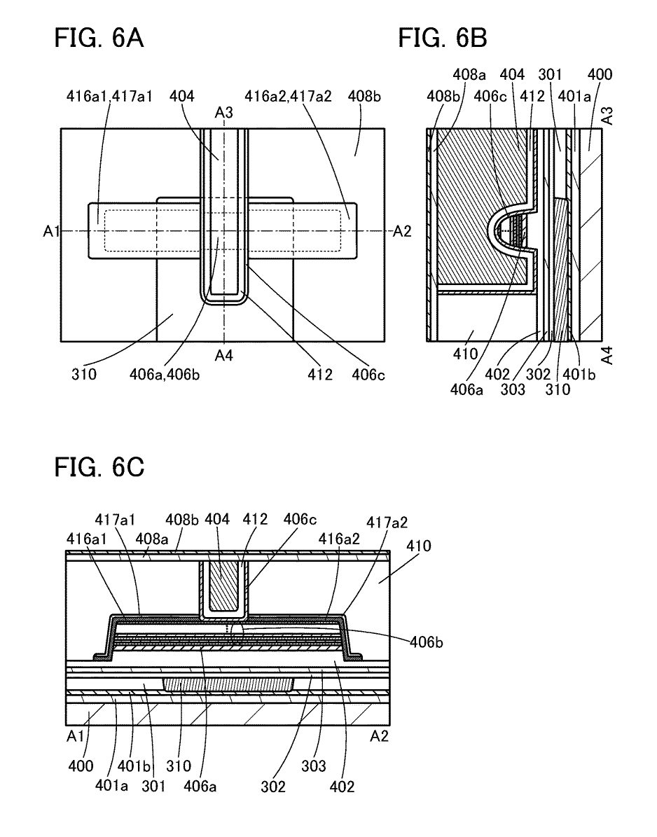

FIGS. 6A to 6C illustrate a transistor having a structure different from that in FIGS. 1A to 1C. FIG. 6A is a top view of a transistor. FIG. 6B is a cross-sectional view taken along the dashed-dotted line A3-A4 in FIG. 6A, or a cross-sectional view in the channel width direction of a channel formation region of the transistor. FIG. 6C is a cross-sectional view taken along the dashed-dotted line A1-A2 in FIG. 6A, or a cross-sectional view in the channel length direction of the transistor. Some components in the top view in FIG. 6A are not illustrated for simplification of the drawing.

The transistor structure 3 is different from the transistor structures 1 and 2 in at least the structure of a gate electrode. In FIGS. 6B and 6C, the transistor is provided over the insulator 401a and the insulator 401b over the substrate 400. The transistor includes the conductor 310 and the insulator 301 over the insulator 401b; the insulator 302 over the conductor 310 and the insulator 301; the insulator 303 over the insulator 302; the insulator 402 over the insulator 303; the oxide 406a over the insulator 402; the oxide 406b over the oxide 406a; the conductor 416a1 and the conductor 416a2 each including a region in contact with the top and side surfaces of the oxide 406b; the oxide 406c including a region in contact with the side surface of the conductor 416a1, the side surface of the conductor 416a2, and the top surface of the oxide 406b; the insulator 412 over the oxide 406c; and the conductor 404 including a region overlapping with the oxide 406c with the insulator 412 therebetween. The insulator 410 has an opening and includes a region overlapping with the conductor 404 with the oxide 406c and the insulator 412 therebetween on the side surface side of the opening. The insulator 301 has an opening, and the conductor 310 is provided in the opening.

The barrier film 417a1 is provided over the conductor 416a1, and the barrier film 417a2 is provided over the conductor 416a2. The insulator 408a and the insulator 408b are provided in this order over the insulator 410, the conductor 404, the oxide 406c, and the insulator 412.

In the transistor, the conductor 404 functions as a first gate electrode. Furthermore, the conductor 404 can have a layered structure including a conductor that has a function of inhibiting the passage of oxygen. For example, when a conductor that has a function of inhibiting the passage of oxygen is formed as a lower layer of the conductor 404, an increase in the electric resistivity due to oxidation of the conductor 404 can be prevented. The insulator 412 functions as a first gate insulator.

The conductors 416a1 and 416a2 function as source and drain electrodes of the transistor. The conductors 416a1 and 416a2 can each have a layered structure including a conductor that has a function of inhibiting the passage of oxygen. For example, when a conductor that has a function of inhibiting the passage of oxygen is formed as un upper layer of each of the conductors 416a1 and 416a2, an increase in the electric resistivity due to oxidation of the conductors 416a1 and 416a2 can he prevented. Note that the electric resistivities of the conductors can be measured by a two-terminal method or the like.

The barrier films 417a1 and 417a2 each have a function of inhibiting the passage of oxygen and impurities such as hydrogen and water. The barrier film 417a1 is located over the conductor 416a1 and prevents the diffusion of oxygen into the conductor 416a1. The barrier film 417a2 is located over the conductor 416a2 and prevents the diffusion of oxygen into the conductor 416a2.

In the transistor, the region functioning as a gate electrode is formed in a self-aligned manner so as to fill an opening formed in the insulator 410 and the like. Such a transistor can also be referred to as a trench-gate-self-aligned s-channel FET (TGSA s-channel FET).

In FIG. 6C, the length of a region of the bottom surface of the conductor 404 functioning as a gate electrode that is parallel to and faces the top surface of the oxide 406b with the insulator 412 and the oxide 406c positioned therebetween is defined as a gate line width. The gate line width can be smaller than the width of the opening formed in the insulator 410 so as to reach the oxide 406b. That is, the gate line width can be smaller than the minimum feature size. Specifically, the gate line width can be 10 nm to 300 nm inclusive, typically 20 nm to 180 nm inclusive.

For the other components and effects, refer to the transistor structure 1.

### <Transistor Structure 4>

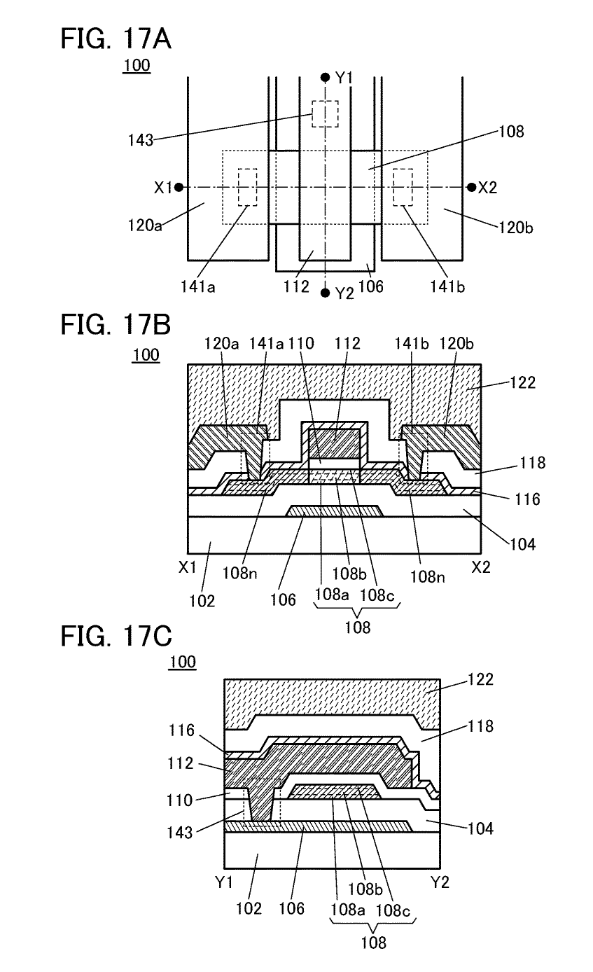

FIG. 17A is a top view of a transistor 100, which is a semiconductor device of one embodiment of the present invention. FIG. 17B is a cross-sectional view taken along the dashed-dotted line X1-X2 in FIG. 17A. FIG. 17C is a cross-sectional view taken along the dashed-dotted line Y1-Y2 in FIG. 17A. Note that in FIG. 17A, some components of the transistor 100 (e.g., an insulator serving as a gate insulator) are not illustrated to avoid complexity. The direction of the dashed-dotted line X1-X2 may be called the channel length direction, and the direction of the dashed-dotted line Y1-Y2 may be called the channel width direction. As in FIG. 17A, some components are not illustrated in some cases in top views of transistors described below.

The transistor 100 illustrated in FIGS. 17A to 17C is what is called a top-gate transistor.

The transistor 100 includes a conductor 106 over a substrate 102; an insulator 104 over the conductor 106; an oxide 108 over the insulator 104; an insulator 110 over the oxide 108; a conductor 112 over the insulator 110; and an insulator 116 over the insulator 104, the oxide 108, and the conductor 112.

The oxide 108 includes regions 108n each of which does not overlap with the conductor 112 and is in contact with the insulator 116. The regions 108n are n-type regions in the oxide 108 described above. Note that the regions 108n are in contact with the insulator 116, and the insulator 116 includes nitrogen or hydrogen. Thus, addition of nitrogen or hydrogen in the insulator 116 to the regions 108n increases carrier density, making the regions 108n have n-type conductivity.

As illustrated in FIGS. 17A to 17C, the transistor 100 may further include a conductor 120a electrically connected to the region 108n through an opening 141a formed in the insulator 116 and an insulator 118; and a conductor 120b electrically connected to the region 108n through an opening 14lb formed in the insulators 116 and 118.

The conductor 112 functions as a first gate electrode (also referred to as a top gate electrode), and the conductor 106 functions as a second gate electrode (also referred to as a bottom gate electrode). The insulator 110 functions as a first gate insulator, and the insulator 104 functions as a second gate insulator. The conductor 120a functions as a source electrode, and the conductor 1201 functions as a drain electrode.

The conductor 106 is electrically connected to the conductor 112 through an opening 143 formed in the insulator 104 and the insulator 110. Thus, the same potential is supplied to the conductor 106 and the conductor 112. Alternatively, the opening 143 is not necessarily provided, and different potentials may be supplied to the conductor 106 and the conductor 112.

The oxide 108 in the channel width direction is entirely covered with the conductor 112 with the insulator 110 therebetween. One of side surfaces of the oxide 108 in the channel width direction faces the conductor 112 with the insulator 110 therebetween. Such a structure enables the oxide 108 included in the transistor 100 to be electrically surrounded by electric fields of the conductor 112 functioning as a first gate electrode and the conductor 106 functioning as a second gate electrode.

In the transistor 100, an electric field for inducing a channel can be effectively applied to the oxide 108 by the conductor 106 or the conductor 112; thus, the current drive capability of the transistor 100 can be improved and high on-state current characteristics can be obtained. Since the on-state current can be increased, the size of the transistor 100 can be reduced.

The insulator 110 includes an excess oxygen region. Since the insulator 110 includes the excess oxygen region, excess oxygen can be supplied to the oxide 108. As a result, oxygen vacancies that might be formed in the oxide 108 can be filled with excess oxygen, and the semiconductor device can have high reliability.

To supply excess oxygen to the oxide 108, excess oxygen may be supplied to the insulator 104 that is formed under the oxide 108. In that case, excess oxygen contained in the insulator 104 might also be supplied to the regions 108n, which is not desirable because the resistance of the regions 108n might be increased. In contrast, in the structure in which the insulator 110 formed over the oxide 108 contains excess oxygen, excess oxygen can be selectively supplied only to a region overlapping with the conductor 112.

Next, components of the transistor 100 will be described.

For details of the substrate 102, refer to the description of the substrate 400 Embodiment 1.

For the insulator 104, any of the materials for the insulator 402 listed in Embodiment 1 can be used. In this embodiment, the insulator 104 has a layered structure of a silicon nitride film and a silicon oxynitride film. With the insulator 104 having such a layered structure of a silicon nitride film as a lower layer and a silicon oxynitride film as an upper layer, oxygen can be efficiently introduced into the oxide 108.

The thickness of the insulator 104 can be greater than or equal to 50 nm, greater than or equal to 100 nm and less than or equal to 3000 nm, or greater than or equal to 200 nm and less than or equal to 1000 nm. By increasing the thickness of the insulator 104, the amount of oxygen released from the insulator 104 can be increased, and interface states at the interface between the insulator 104 and the oxide 108 and oxygen vacancies included in the oxide 108 can be reduced.

For the conductor 112, the same material as that for the conductor 404 in Embodiment 1 can be used. For the conductor 106, the same material as that for the conductor 310 in Embodiment 1 can be used.

The conductors 120a and 120b can be formed using a metal element selected from chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co); an alloy including any of these metal elements as its component; an alloy of a combination of any of these metal elements; or the like.

Furthermore, for the conductors 112, 106, 120a, and 120b, an oxide conductor or a metal oxide such as an oxide including indium and tin (In—Sn oxide), an oxide including indium and tungsten (In—W oxide), an oxide including indium, tungsten, and zinc (In—W—Zn oxide), an oxide including indium and titanium (In—Ti oxide), an oxide including indium, titanium, and tin (In—Ti—Sn oxide), an oxide including indium and zinc (In—Zn oxide), an oxide including indium, tin, and silicon (In—Sn—Si oxide), or an oxide including indium, gallium, and zinc (In—Ga—Zn oxide) can alternatively be used.

Here, an oxide conductor will be described. In this specification and the like, an oxide conductor can also be referred to as OC. For example, when oxygen vacancies are formed in a metal oxide and hydrogen is added to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor. A metal oxide generally has a visible light transmitting property because of its large energy gap. An oxide conductor is a metal oxide having a donor level in the vicinity of the conduction band. Therefore, the influence of absorption due to the donor level is small in an oxide conductor, and an oxide conductor has a visible light transmitting property comparable to that of a metal oxide.

It is particularly preferred to use the oxide conductor described above as the conductor 112, in which case excess oxygen can be added to the insulator 110.

For the insulator 110, any of the materials for the insulator 412 that are listed in Embodiment 1 can be used. Note that the insulator 110 may have a two-layer structure or a layered structure including three or more layers.

It is preferable that the insulator 110 have few defects and typically have as few signals observed by electron spin resonance (ESR) spectroscopy as possible. Examples of the signals include a signal due to an E′ center observed at a g-factor of 2,001. Note that the E′ center is due to the dangling bond of silicon. As the insulator 110, a silicon oxide film or a silicon oxynitride film whose spin density due to the E′ center is lower than or equal to 3×10¹⁷ spins/cm³, preferably lower than or equal to 5×10¹⁶ spins/cm³ can be used.

As the oxide 108, the oxide 406b described in Embodiment 1 can be used. FIGS. 17A to 17C illustrate an example in which the oxide 108 consists of three layers of oxides 108a, 108b, and 108c stacked in this order. The oxides 108a and 108c may each be the oxide having the first band gap that is described in Embodiment 1, and the oxide 108b may be the oxide having the second band gap that is described in Embodiment 1. Alternatively, the oxides 108a and 108c may each be the oxide having the second band gap that is described in Embodiment 1, and the oxide 108b may be the oxide having the first hand gap that is described in Embodiment 1.

The insulator 116 includes nitrogen or hydrogen. As the insulator 116, for example, a nitride insulator can be used. The nitride insulator can be formed using silicon nitride, silicon nitride oxide, silicon oxynitride, or the like. The hydrogen concentration in the insulator 116 is preferably higher than or equal to 1×10²² atoms/cm³. Furthermore, the insulator 116 is in contact with the regions 108n of the oxide 108. Thus, the concentration of an impurity (nitrogen or hydrogen) in the regions 108n in contact with the insulator 116 is increased, leading to an increase in the carrier density of the regions 108n.

As the insulator 118, an oxide insulator can he used. Alternatively, a stack of an oxide insulator and a nitride insulator can be used as the insulator 118. The insulating film 118 can be formed using, for example, silicon oxide, silicon oxynitride, silicon nitride oxide, aluminum oxide, hafnium oxide, gallium oxide, or Ga—Zn oxide.

Furthermore, the insulator 118 preferably functions as a barrier film against hydrogen, water, and the like from the outside.

The thickness of the insulator 118 can be greater than or equal to 30 nm and less than or equal to 500 nm, or greater than or equal to 100 nm and less than or equal to 400 nm.

### <Transistor Structure 5>

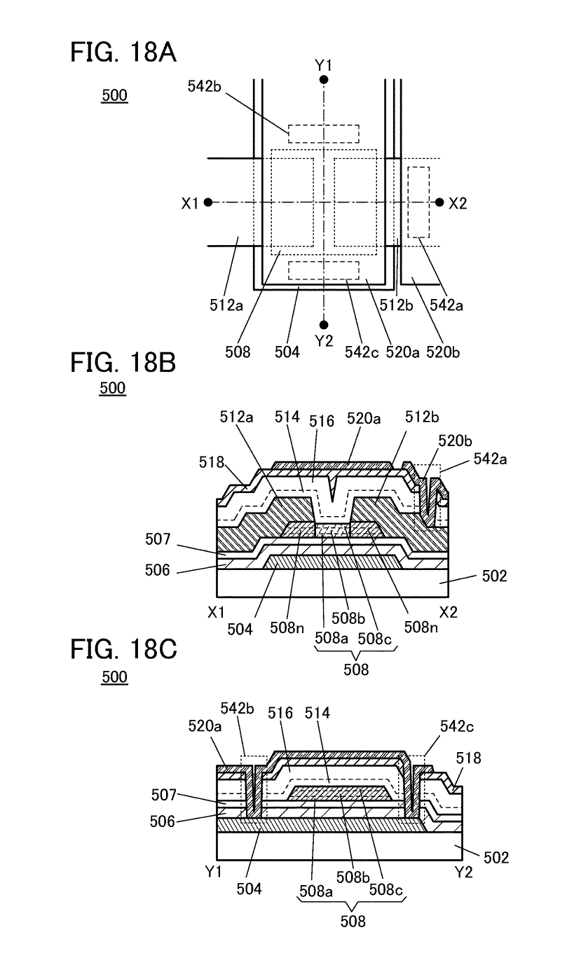

FIG. 18A is a top view of the transistor 500. FIG. 18B is a cross-sectional view taken along the dashed-dotted line X1-X2 in FIG. 18A. FIG. 18C is a cross-sectional view taken along the dashed-dotted line Y1-Y2 in FIG. 18A.

The transistor 500 illustrated in FIGS. 18A to 18C includes a conductor 504 over a substrate 502; an insulator 506 over the substrate 502 and the conductor 504; an insulator 507 over the insulator 506; an oxide 508 over the insulator 507; a conductor 512a over the oxide 508; a conductor 512b over the oxide 508; an insulator 514 over the oxide 508 and the conductors 512a and 512b; an insulator 516 over the insulator 514; an insulator 518 over the insulator 516; and conductors 520a and 520b over the insulator 518.

Note that in the transistor 500, the insulators 506 and 507 function as a first gate insulator of the transistor 500, and the insulators 514, 516, and 518 function as a second gate insulator of the transistor 500. In addition, in the transistor 500, the conductor 504 functions as a first gate electrode, the conductor 520a functions as a second gate electrode, and the conductor 520b functions as a pixel electrode used for a display device. The conductor 512a functions as a source electrode, and the conductor 512b functions as a drain electrode.

As illustrated in FIG. 18C, the conductor 520a is connected to the conductor 504 through openings 542b and 542c formed in the insulators 506, 507, 514, 516, and 518. Accordingly, the same potential is supplied to the conductor 520a and the conductor 504.

The conductor 520b is connected to the conductor 512b through an opening 542a formed in the insulators 514, 516, and 518.

As the oxide 508, the oxide 406b described in Embodiment 1 can be used. FIGS. 18A to 18C illustrate an example in which the oxide 508 consists of three layers of oxides 508a, 508b, and 508c stacked in this order. The oxides 508a and 508c may each be the oxide having the first band gap that is described in Embodiment 1, and the oxide 508b may be the oxide having the second band gap that is described in Embodiment 1. Alternatively, the oxides 508a and 508c may each be the oxide having the second band gap that is described in Embodiment 1, and the oxide 508b may be the oxide having the first band gap that is described in Embodiment 1.

The oxide 508 includes regions 508n in contact with the conductors 512a and 512b. The regions 508n are n-type regions of the oxide 508. The regions 508n in the oxide 508 contribute to a reduction in contact resistance between the oxide 508 and each of the conductors 512a and 512b. The regions 508n are formed when oxygen in the oxide 508 is extracted by the conductors 512a and 512b. Oxygen is more likely to be extracted at a higher temperature. Oxygen vacancies are formed in the regions 508n through several heating steps in the manufacturing process of the transistor. In addition, hydrogen enters sites of the oxygen vacancies by heating, increasing the carrier concentration in the regions 508n. Consequently, the resistance of the regions 508n is reduced.

The oxide 508 in the channel width direction is entirely covered with the conductor 520a with the insulators 516 and 514 therebetween. One of side surfaces of the oxide 508 in the channel width direction faces the conductor 520a with the insulators 516 and 514 therebetween. Such a structure enables the oxide 508 included in the transistor 500 to be electrically surrounded by electric fields of the conductor 504 and the conductor 520a.

In the transistor 500, an electric field for inducing a channel can be effectively applied to the oxide 508 by the conductor 504 or the conductor 520a; thus, the current drive capability of the transistor 500 can be improved and high on-state current characteristics can be obtained. Since the on-state current can be increased, the size of the transistor 500 can be reduced.

The structures, methods, and the like described in this embodiment can be combined with any of the structures, methods, and the like described in the other embodiments as appropriate.

### Embodiment 2

### <Method for Manufacturing Transistor>

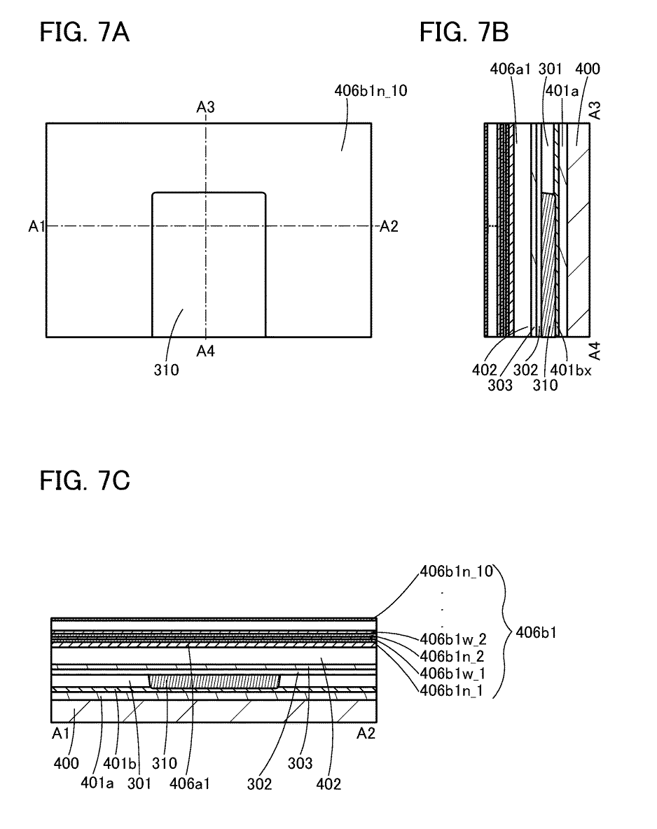

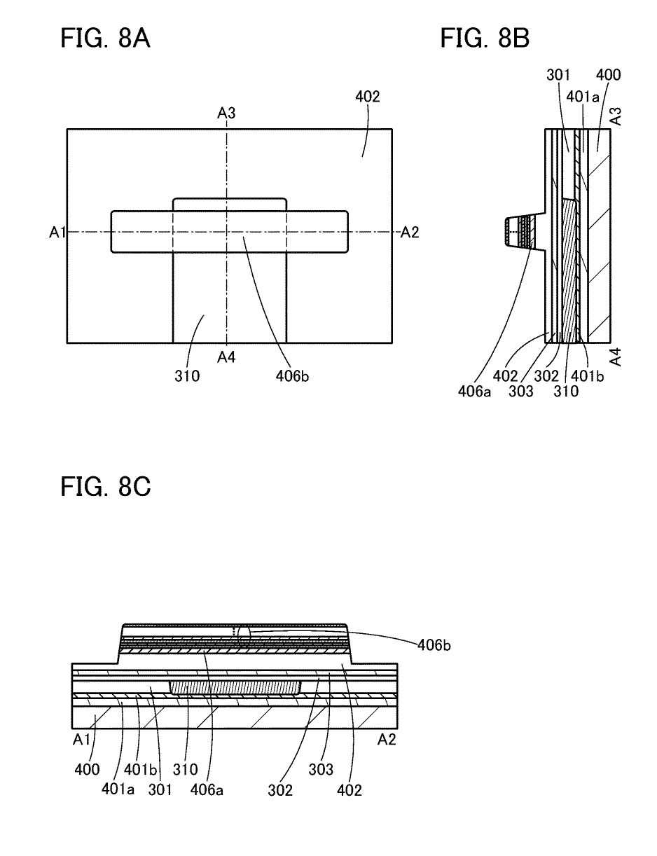

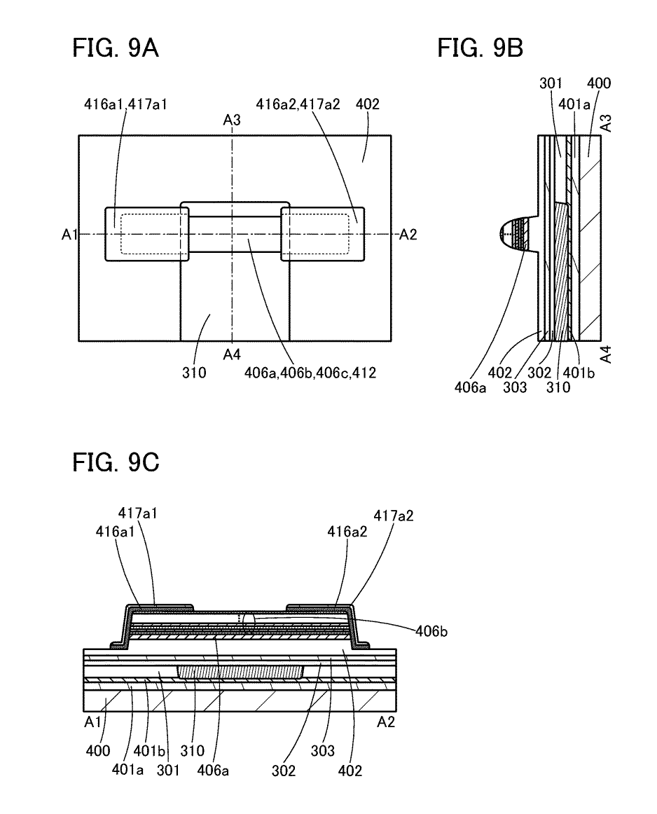

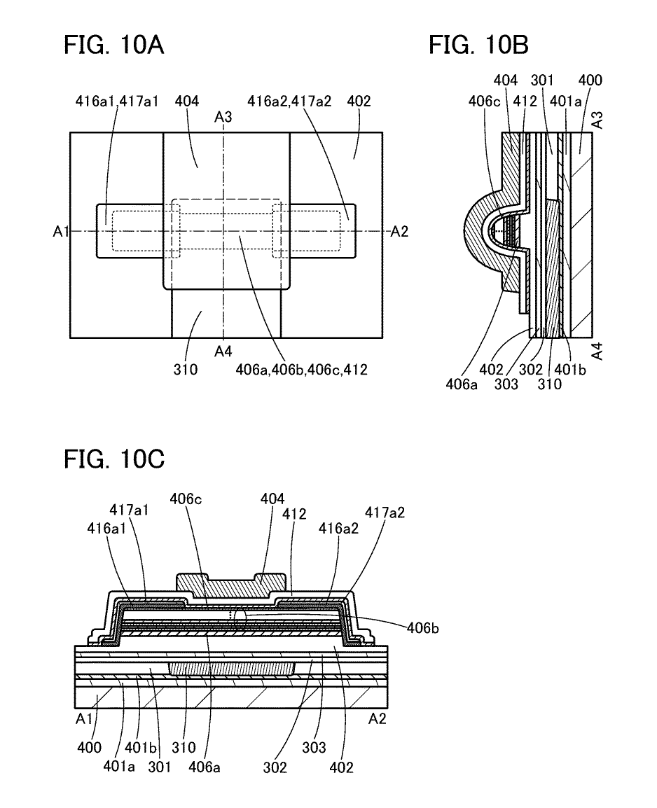

A method for manufacturing the transistor of one embodiment of the present invention illustrated in FIGS. 1A to 1C will be described below with reference to FIGS. 1A to 1C and FIGS. 7A to 7C to FIGS. 10A to 10C. FIG. 1A. FIG. 7A. FIG. 8A. FIG. 9A, and FIG. 10A are each a top view. FIG. 1B. FIG. 7B. FIG. 8B. FIG. 9B, and FIG. 10B are each a cross-sectional view taken along the dashed-dotted line A3-A4 in FIG. 1A. FIG. 7A. FIG. 8A. FIG. 9A, and FIG. 10A. FIG. 1C. FIG. 7C. FIG. 5C. FIG. 9C, and FIG. 1OC are each a cross-sectional view taken along the dashed-dotted line A1-A2 in FIG. 1A. FIG. 7A. FIG. 8A. FIG. 9A, and FIG. 10A.

First, the substrate 400 is prepared.

Then, the insulator 401a is formed. The insulator 401a can be formed by a sputtering method, a chemical vapor deposition (CVD) method, a molecular beam epitaxy (MBE) method, a pulsed laser deposition (PLD) method, an atomic layer deposition (ALD) method, or the like.

Note that CVD methods can be classified into a plasma enhanced CVD (PECVD) method using plasma, a thermal CVD (TCVD) method using heat, a photo CND method using light, and the like. Moreover, the CVD methods can be classified into a metal CVD (MCVD) method and a metal organic CVD (MOCVD) method depending on a source gas.

In the case of a PECVD method, a high quality film can be obtained at relatively low temperature. Furthermore, a TCVD method does not use plasma and thus causes less plasma damage to an object. For example, a wiring, an electrode, an element (e.g., a transistor or a capacitor), or the like included in a semiconductor device might be charged up by receiving electric charge from plasma. In that case, accumulated electric charge might break the wiring, electrode, element, or the like included in the semiconductor device. Such plasma damage is not caused in the case of using a TCVD method not using plasma, and thus the yield of a semiconductor device can be increased. In addition, since plasma damage does not occur in the deposition by a TCVD method, a film with few defects can be obtained.

An ALD method also causes less plasma damage to an object. An ALD method does not cause plasma damage during deposition, so that a film with few defects can be obtained.

Unlike in a deposition method in which particles released from a target or the like are deposited, in a CVD method and an ALD method, a film is formed by a reaction at a surface of an object. Thus, a CVD method and an ALD method enable favorable step coverage almost regardless of the shape of an object. In particular, an ALD method enables excellent step coverage and excellent thickness uniformity and can be favorably used to cover a surface of an opening with a high aspect ratio, for example. On the other hand, an ALD method has a relatively low deposition rate; thus, it is sometimes preferable to combine an ALD method with another deposition method with a high deposition rate, such as a CVD method.

When a CVD method or an ALD method is used, the composition of a film to be formed can be controlled with a flow rate ratio of the source gases. For example, with a CVD method or an ALD method, a film with a desired composition can be formed by adjusting the flow rate ratio of the source gases. Moreover, with a CVD method or an ALD method, by changing the flow rate ratio of the source gases while forming a film, the film whose composition is continuously changed can be formed. In the case where a film is formed while changing the flow rate ratio of the source gases, as compared to the ease where a film is formed using a plurality of deposition chambers, time taken for the deposition can be reduced because time taken for transfer and pressure adjustment is omitted. Thus, semiconductor devices can be manufactured with improved productivity.

Next, the insulator 401b is formed over the insulator 401a. The insulator 401b can be formed by a sputtering method, a CVD method, a MBE method, a PLD method, an ALD method, or the like. Then, the insulator 301 is formed over the insulator 401b. The insulator 301 can be formed by a sputtering method, a CVD method, a MBE method, a PLD method, an ALD method, or the like.

Then, a groove is formed in the insulator 301 so as to reach the insulator 401b. Examples of the groove include a hole and an opening. In forming the groove, wet etching may be employed; however, dry etching is preferably employed in terms of microfabrication. The insulator 401b is preferably an insulator that functions as an etching stopper film used in forming the groove by etching the insulator 301. For example, in the case where a silicon oxide film is used as the insulator 301 in which the groove is to be formed, the insulator 401b is preferably formed using a silicon nitride film, an aluminum oxide film, or a hafnium oxide film.

In this embodiment, aluminum oxide is deposited as the insulator 401a by an ALD method, and aluminum oxide is deposited as the insulator 401b by a sputtering method.

After the formation of the groove, a conductor to be the conductor 310 is formed. The conductor to be the conductor 310 desirably includes a conductor that has a function of inhibiting the passage of oxygen. For example, tantalum nitride, tungsten nitride, or titanium nitride can be used. Alternatively, a layered film formed using the conductor and tantalum, tungsten, titanium, molybdenum, aluminum, copper, or a molybdenum-tungsten alloy can be used. The conductor to be the conductor 310 can be formed by a sputtering method, a CVD method, an MBE method, a PLD method, an ALD method, or the like.

In this embodiment, as a conductor to be the conductor 310, tantalum nitride is deposited by a sputtering method, titanium nitride is deposited over the tantalum nitride by a CVD method, and tungsten is deposited over the titanium nitride by a CVD method.

Next, chemical mechanical polishing (CMP) is performed to remove the conductor to be the conductor 310 over the insulator 301. Consequently, the conductor to be the conductor 310 remains only in the groove, whereby the conductor 310 with a flat top surface can be formed.

Next, the insulator 302 is formed over the insulator 301 and the conductor 310. The insulator 302 can be formed by a sputtering method, a CVD method, an MBE method, a PLD method, an ALD method, or the like.

Then, the insulator 303 is formed over the insulator 302. The insulator 303 can be formed by a sputtering method, a CVD method, an MBE method, a PLD method, an ALD method, or the like.

Next, the insulator 402 is formed over the insulator 303. The insulator 402 can be formed by a sputtering method, a CVD method, an MBE method, a PLD method, an ALD method, or the like.

Next, first heat treatment is preferably performed. The first heat treatment can be performed at a temperature higher than or equal to 250° C. and lower than or equal to 650° C., preferably higher than or equal to 450° C. and lower than or equal to 600° C., more preferably higher than or equal to 520° C. and lower than or equal to 570° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. By the first heat treatment, impurities such as hydrogen and water included in the insulator 402 can be removed, for example. Alternatively, in the first heat treatment, plasma treatment using oxygen may he performed under a reduced pressure. The plasma treatment containing oxygen is preferably performed using an apparatus including a power source for generating high-density plasma using microwaves, for example. Alternatively, a power source for applying a radio frequency (RF) to a substrate side may be provided. The use of high-density plasma enables high-density oxygen radicals to be produced, and application of the RE to the substrate side allows oxygen radicals generated by the high-density plasma to be efficiently introduced into the insulator 402. Alternatively, after plasma treatment using an inert gas with the apparatus, plasma treatment using oxygen in order to compensate released oxygen may be performed. Note that first heat treatment is not necessarily performed in some cases.

Next, an oxide 406a1 is formed over the insulator 402. The oxide 406a1 can be formed by a sputtering method, a CVD method, an MBE method, a PLD method, an ALD method, or the like.

Next, treatment to add oxygen to the oxide 406a1 may be performed. Examples of the treatment for adding oxygen to the oxide 406a1 include an ion implantation method and a plasma treatment method. Note that oxygen added to the oxide 406a1 is excess oxygen.

Next, an oxide 406b1 is formed over the oxide 406a1 (see FIGS. 7A to 7C). The oxide 406b1 is preferably formed by a sputtering method. In this embodiment, the thickness of each of an oxide 406b1n having the first band gap and an oxide 406b1w having the second band gap is set to 1 nm, and ten oxides 406b1n each having the first band gap are formed. Thus, the oxide 406b1 has a 19-layer structure with a total thickness of 19 nm.

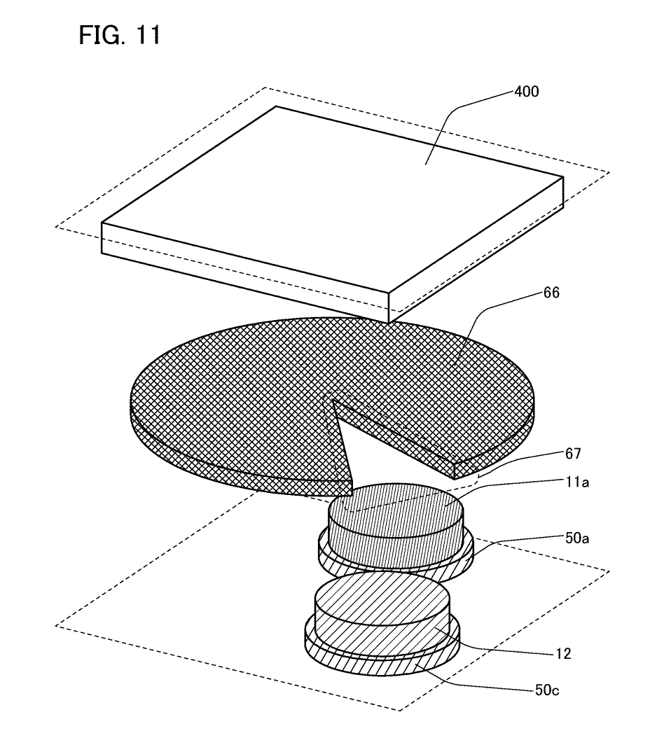

A deposition chamber of a sputtering apparatus that can be used for formation of the oxide 406b1 will be described below with reference to FIG. 11.

As illustrated in FIG. 11, the sputtering apparatus described in this embodiment includes a sputtering target 11a, a sputtering target 12, and a shutter 66 provided with a cut portion 67 (also referred to as a slit portion). The substrate 400 can be positioned to face the sputtering target H a and the sputtering target 12. The sputtering target 11a is positioned over a backing plate 50a. Similarly, the sputtering target 12 is positioned over a backing plate 50c.

Here, the sputtering target 11a includes a conductive material and is used to form the oxide 406b1n having the first band gap. The sputtering target 12 includes an insulating material (also referred to as a dielectric material) and is used to form the oxide 406b1w having the second band gap. The conductive material preferably includes indium and/or zinc, for example. Alternatively, the conductive material preferably includes an oxide, a nitride, and/or an oxynitride of indium and/or zinc. The insulating material preferably includes the element M (the element M is one or more of Ga, Al, Si, B, Y, Ti, Fe, Ni, Ge, Zr, Mo, La, Ce, Nd, Hf, Ta, W, Mg, V, Be, and Cu). Alternatively, the insulating material preferably includes an oxide, a nitride, and/or an oxynitride of the element M.

For example, the sputtering target 11a can include indium oxide, and the sputtering target 12 can include an oxide of the element M.

The shutter 66 is located between the sputtering targets 11a and 12 and the substrate 400 (or a substrate holder where the substrate 400 is positioned).

The shutter 66 can preferably rotate about an axis perpendicular to the top surface or the bottom surface of the shutter 66 (hereinafter the axis may be referred to as an axis perpendicular to the shutter 66) as a rotation axis. Rotating the shutter 66 allows selection of the sputtering target facing the substrate 400 (substrate holder) with the cut portion 67 therebetween.

When the shutter 66 rotates in deposition and the cut portion 67 overlaps with the sputtering target 11a, sputtered particles ejected from the sputtering target 11a are mainly deposited on the substrate 400. Similarly, when the cut portion 67 overlaps with the sputtering target 12, sputtered particles ejected from the sputtering target 12 are mainly deposited on the substrate 400.

By performing deposition in such a manner, the oxides 406b1n each including, as its main component, the conductive material included in the sputtering target 11a and the oxides 406b1w each including, as its main component, the insulating material included in the sputtering target 12 can alternately be stacked. This allows formation of the oxide 406b1 having a multilayer structure in which the oxides 406b1n each having the first band gap and the oxides 406b1w each having the second band gap are alternately stacked.

Note that sputtered particles are ejected from all targets in deposition; thus, sputtered particles ejected from the target not overlapping with the cut portion 67 are deposited on the substrate 400 in some cases. That is to say, the oxides 406b1w might include the conductive material, or the oxides 406b1n might include the insulating material.

The temperature of the substrate 400 can be higher than or equal to room temperature (25° C.) and lower than or equal to 150° C., preferably higher than or equal to room temperature and lower than or equal to 130° C. When the temperature of the substrate 400 is higher than or equal to 100° C. and lower than or equal to 130° C., water in the oxides can be removed. Removing water, which is an impurity, in such a manner leads to high field-effect mobility and high reliability.

When deposition is performed with the temperature of the substrate 400 set to higher than or equal to room temperature and lower than or equal to 150° C., shallow defect states (also referred to as sDOS) of the oxides can be reduced.

As a deposition gas, one or more of an argon gas, an oxygen gas, and a nitrogen gas can be introduced. Note that instead of an argon gas, an inert gas such as helium, xenon, or krypton can be used.

In the case where the oxides are formed using an oxygen gas, higher carrier mobility of the oxides can be achieved with a lower flow rate ratio of oxygen. The oxygen flow rate ratio can be appropriately set in the range from 0% to 30% inclusive so that favorable characteristics of the oxides suitable to the uses can be obtained. For example, a mixed gas of an argon gas and an oxygen gas can be used as the deposition gas. Furthermore, when the deposition gas including an oxygen gas is used, the amount of oxygen vacancies in the oxides that are formed can be reduced. Reducing the amount of oxygen vacancies leads to high reliability of the oxides.

The flow rate ratio of nitrogen can be appropriately set in the range from 10% to 100% inclusive so that favorable characteristics of the oxides suitable to the uses can be obtained. For example, a mixed gas of a nitrogen gas and an argon gas can be used as the deposition gas. Alternatively, a mixed gas of a nitrogen gas and an oxygen gas or a mixed gas of a nitrogen gas, an oxygen gas, and an argon gas may be used.

In addition, increasing the purity of a sputtering gas is necessary. For example, as an oxygen gas, a nitrogen gas, or an argon gas used as a sputtering gas, a gas which is highly purified to have a dew point of −40° C. or lower, preferably −80° C. or lower, more preferably −100° C. or lower, still more preferably −120° C. or lower is used, whereby entry of moisture or the like into the oxides can be minimized.

In the case where the oxides are formed by a sputtering method, a chamber in a sputtering apparatus is preferably evacuated to be a high vacuum state (approximately 5×10⁻⁷ Pa to 1×10⁻⁴ Pa) with an adsorption vacuum evacuation pump such as a cryopump. Alternatively, a turbo molecular pump and a cold trap are preferably used in combination to prevent backflow of a gas into the chamber through an evacuation system.

In addition, a DC power source, an AC power source, or an RF power source can be used as a power source of the sputtering apparatus.

After that, second heat treatment may be performed. For the second heat treatment, the conditions for the first heat treatment can be used. By the second heat treatment, the crystallinity of the oxide 406b1 can be increased and impurities such as hydrogen and water can be removed from the oxide 406b1. Preferably, treatment at 400° C. In a nitrogen atmosphere for one hour and treatment at 400° C. In an oxygen atmosphere for one hour are successively performed in this order.

Then, a resist mask is formed over the oxide 406b1 by a lithography method, and the oxide 406b1 and the oxide 406a1 are etched. For etching of the oxide 406b1 and the oxide 406a1, a dry etching method can be employed. The oxide 406b1 has a structure where oxides each having the first band gap and oxides each having the second band gap are alternately stacked. A dry etching apparatus that can easily change etching conditions between the conditions for etching the oxide having the first band gap and the conditions for etching the oxide having the second band gap in accordance with the structure is preferably used. Note that the oxide having the first hand gap and the oxide having the second band gap can be etched under the same conditions in some cases. Following the etching of the oxide 406b1, etching of the oxide 406a1 is performed, so that the oxide 406b and the oxide 406a are formed (see FIGS. 8A to 8C).

In a lithography method, first, a resist is exposed to light through a photomask. Next, a region exposed to light is removed or left using a developing solution, so that a resist mask is formed. Then, etching through the resist mask is conducted. As a result, the conductor, the semiconductor, the insulator, or the like can be processed into a desired shape. The resist mask is formed by, for example, exposure of the resist to light using KrF excimer laser light, ArF excimer laser light, extreme ultraviolet (EUV) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a photomask is not necessary in the case of using an electron beam or an ion beam. Note that dry etching treatment such as aching or wet etching treatment can be used for removal of the resist mask. Alternatively, wet etching treatment is performed after dry etching treatment. Still alternatively, dry etching treatment is performed after wet etching treatment.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, the capacitively coupled plasma etching apparatus may have a structure in which different high-frequency power sources are applied to one of the parallel plate type electrodes. Alternatively, the capacitively coupled plasma etching apparatus may have a structure in which high-frequency power sources with the same frequency are applied to the parallel plate type electrodes. Alternatively, the capacitively coupled plasma etching apparatus may have a structure in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

Then, a conductor to be the conductor 416a1 and the conductor 416a2 is formed over the oxide 406b. The conductor to be the conductor 416a1 and the conductor 416a2 can be formed by a sputtering method, a CVD method, an MBE method, a PLD method, an ALD method, or the like. As the conductor to be the conductor 416a1 and the conductor 416a2, a conductive oxide such as indium tin oxide, indium oxide including tungsten oxide, indium zinc oxide including tungsten oxide, indium oxide including titanium oxide, indium tin oxide including titanium oxide, indium zinc oxide, indium tin oxide to which silicon is added, or indium gallium zinc oxide including nitrogen is deposited, and a material including one or more of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, and the like, a semiconductor with high electric conductivity, typified by polycrystalline silicon including an impurity element such as phosphorus, or a silicide such as nickel silicide may be deposited over the oxide.

The oxide may have a function of absorbing hydrogen in the oxide 406a and the oxide 406b and capturing hydrogen diffused from the outside; thus, the electrical characteristics and reliability of the transistor are improved in some cases. Titanium instead of the oxide may have a similar function.

Next, a barrier film to he the harrier film 417a1 and the barrier film 417a2 is formed over the conductor to be the conductor 416a1 and the conductor 416a2. The barrier film to be the barrier film 417a1 and the barrier film 417a2 can be formed by a sputtering method, a CVD method, an MBE method, a PLD method, an ALD method, or the like. In this embodiment, aluminum oxide is deposited as the barrier film to be the barrier film 417a1 and the barrier film 417a2.

Then, the conductor 416a1, the conductor 416a2, the barrier film 417a1, and the barrier film 417a2 are formed by a lithography method (see FIGS. 9A to 9C).

Then, washing treatment may be performed using an aqueous solution in which hydrofluoric acid is diluted with pure water (diluted hydrogen fluoride solution). A diluted hydrogen fluoride solution refers to a solution in which hydrofluoric acid is mixed into pure water at a concentration of approximately 70 ppm. Next, third heat treatment is performed. For the third heat treatment, the conditions for the first heat treatment can be used. Preferably, treatment at 400° C. In a nitrogen atmosphere for one hour and treatment at 400° C. In an oxygen atmosphere for one hour are successively performed in this order.

In some cases, dry etching performed in the above process causes the attachment or diffusion of an impurity due to an etching gas to a surface or an inside portion of the oxide 406a, the oxide 406b, or the like. The impurity is fluorine or chlorine, for example.

The above treatment allows a reduction in impurity concentration. Furthermore, the moisture concentration and the hydrogen concentration in the oxide 406a and the oxide 406b can be reduced.

Then, an oxide to be the oxide 406c is deposited. The oxide can be deposited by a sputtering method, a CVD method, an MBE method, a PLD method, an ALD method, or the like. A sputtering method is especially preferred for the deposition. Furthermore, sputtering conditions are as follows: a mixed gas of oxygen and argon is used; the oxygen partial pressure is preferably high, more preferably 100%; and the deposition temperature is room temperature or higher than or equal to 100° C. and lower than or equal to 200° C.

The oxide to be the oxide 406c is preferably deposited under the above conditions, in which case excess oxygen can be introduced into the oxide 406a, the oxide 406b, and the insulator 402.

Next, an insulator to be the insulator 412 is deposited over the oxide to be the oxide 406c. The insulator to be the insulator 412 can be deposited by a sputtering method, a CVD method, an MBE method, a PLD method, an AM method, or the like.

Here, fourth heat treatment can be performed. For the fourth heat treatment, the conditions for the first heat treatment can be used. Preferably, treatment at 400° C. In a nitrogen atmosphere for one hour and treatment at 400° C. In an oxygen atmosphere for one hour are successively performed in this order. The moisture concentration and the hydrogen concentration in the insulator to be the insulator 412 can be reduced by the fourth heat treatment.

Next, a conductor to be the conductor 404 is deposited. The conductor to be the conductor 404 can be deposited by a sputtering method, a CVD method, an MBE method, a PLD method, an AM method, or the like.

The conductor to be the conductor 404 may be a multilayer film. For example, an oxide is deposited using conditions similar to those for the deposition of the oxide to be the oxide 406c so that oxygen can be added to the insulator to be the insulator 412. Oxygen added to the insulator to be the insulator 412 is excess oxygen.

Then, a conductor is deposited over the oxide by a sputtering method, whereby the electric resistivity of the oxide can be decreased.

The conductor to be the conductor 404 is processed by a lithography method to form the conductor 404. After that, the oxide to be the oxide 406c and the insulator to be the insulator 412 are processed by a lithography method to form the oxide 406c and the insulator 412 (see FIGS. 10A to 10C). Note that although the example in which the oxide 406c and the insulator 412 are formed after the conductor 404 is formed is described in this embodiment, the following procedure may alternatively be employed: the conductor 404 is formed after formation of the oxide 406c and the insulator 412.

Next, the insulator 408a is formed, and the insulator 408b is formed over the insulator 408a. The insulator 408a and the insulator 408b can be formed by a sputtering method, a CVD method, an MBE method, a PLD method, an ALD method, or the like. In the case where aluminum oxide is deposited as the insulator 408b by an ALD method, the insulator 408b can be formed to have an even thickness and few pin holes on the top and side surfaces of the insulator 408a, resulting in prevention of oxidation of the conductor 404.

Next, the insulator 410 is formed over the insulator 408b. The insulator 410 can be formed by a sputtering method, a CVD method, an MBE method, a PLD method, an ALD method, or the like. Alternatively, the insulator 410 can be formed by a spin coating method, a dipping method, a droplet discharging method (such as an ink-jet method), a printing method (such as screen printing or offset printing), a doctor knife method, a roll coater method, a curtain coater method, or the like.

For the formation of the insulator 410, a CVD method is preferably employed. More preferably, a plasma CVD method is employed. In the case of film formation by a plasma CVD method, a step 1 of depositing an insulator and a step 2 of performing plasma treatment in an atmosphere containing oxygen may be repeatedly conducted. By conducting the step 1 and the step 2 more than once, the insulator 410 including excess oxygen can be formed.

The insulator 410 may be formed to have a fiat top surface. For example, the top surface of the insulator 410 may have planarity immediately after the deposition. Alternatively, the insulator 410 may be planarized by removing the insulator or the like from the top surface after the deposition so that the top surface becomes parallel to a reference surface such as a rear surface of the substrate. Such treatment is referred to as planarization treatment. As the planarization treatment, for example. CMP treatment, dry etching treatment, or the like can be performed. Note that the top surface of the insulator 410 is not necessarily flat.

Next, fifth heat treatment may be performed. For the fifth heat treatment, the conditions for the first heat treatment can be used. Preferably, treatment at 400° C. In a nitrogen atmosphere for one hour and treatment at 400° C. In an oxygen atmosphere for one hour are successively performed in this order. The moisture concentration and the hydrogen concentration in the insulator 410 can be reduced by the fifth heat treatment. Through the above steps, the transistor illustrated in FIGS. 1A to 1C can be fabricated (see FIGS. 1A to IC).

The structures, methods, and the like described in this embodiment can be combined with any of the structures, methods, and the like described in the other embodiments as appropriate.

### Embodiment 3

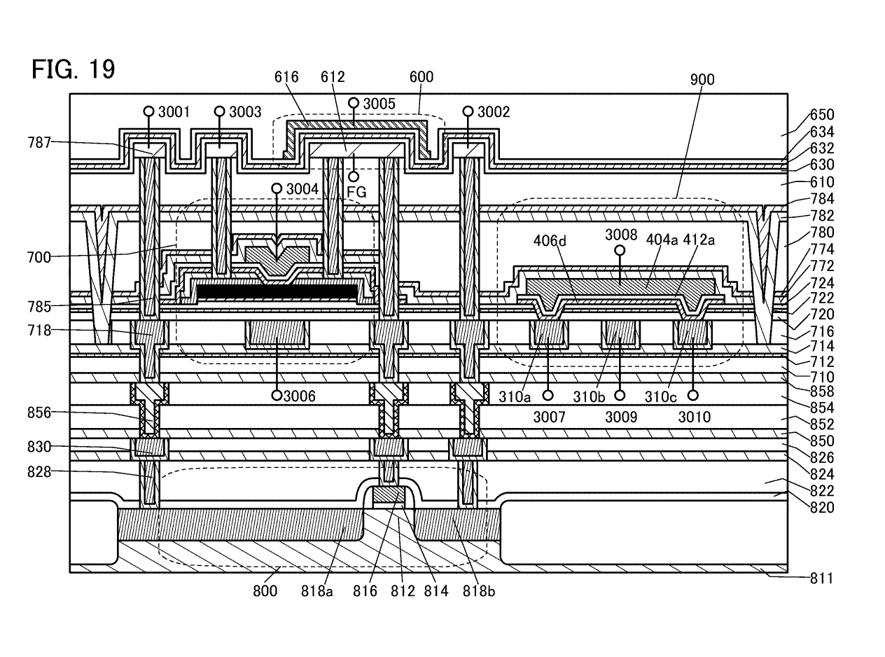

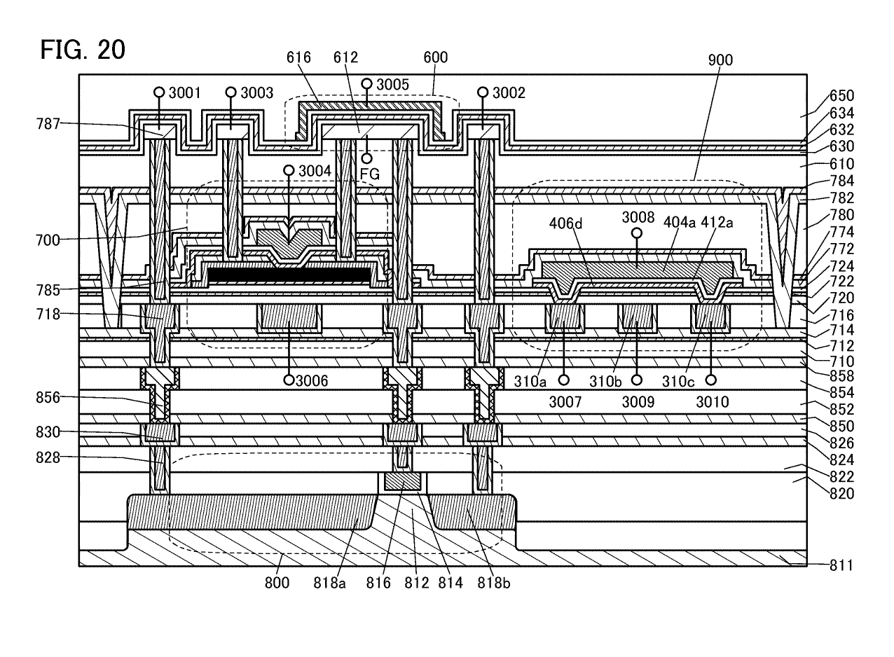

In this embodiment, embodiments of semiconductor devices will be described with reference to FIGS. 19 and 20.

### [Memory Device]

FIGS. 19 and 20 each illustrate an example of a memory device using the semiconductor device of one embodiment of the present invention.

The memory devices in FIGS. 19 and 20 each include a transistor 900, a transistor 800, a transistor 700, and a capacitor 600.

The transistor 700 is similar to that described in the above embodiment with reference to FIGS. 1A to 1C or the like. An insulator 712 illustrated in FIGS. 19 and 20 corresponds to the insulator 401a. An insulator 714 corresponds to the insulator 401b. An insulator 716 corresponds to the insulator 301. An insulator 720 corresponds to the insulator 302. An insulator 722 corresponds to the insulator 303. An insulator 724 corresponds to the insulator 402. An insulator 772 corresponds to the insulator 408a. An insulator 774 corresponds to the insulator 408b. An insulator 780 corresponds to the insulator 410.

The transistor 700 is a transistor in which a channel is formed in a semiconductor layer including an oxide semiconductor. Since the off-state current of the transistor 700 is small, by using the transistor 700 in a memory device, stored data can be retained for a long time. In other words, such a memory device does not require refresh operation or has an extremely low frequency of the refresh operation, which leads to a sufficient reduction in power consumption.

Moreover, supplying a negative potential to a back gate of the transistor 700 can further reduce the off-state current of the transistor 700. In that case, with a structure capable of maintaining the back gate voltage of the transistor 700, stored data can be retained for a long time without power supply.

The transistor 900 and the transistor 700 are formed over the same layer, and thus, the transistor 900 can be formed in parallel with the transistor 700. In the transistor 900, the insulator 716 has openings in which a conductor 310a, a conductor 310b, and a conductor 310c are provided; the insulator 720, the insulator 722, and the insulator 724 are provided over the conductor 310a, the conductor 310b, the conductor 310c, and the insulator 716; an oxide 406d is provided over the insulator 724; an insulator 412a is provided over the oxide 406d; and a conductor 404a is provided over the insulator 412a. Here, the conductor 310a, the conductor 310b, and the conductor 310c are formed in the same layer as the conductor 310. The oxide 406d is formed in the same layer as the oxide 406c. The insulator 412a is formed in the same layer as the insulator 412. The conductor 404a is formed in the same layer as the conductor 404.

The conductors 310a and 310c are in contact with the oxide 406d through openings formed in the insulators 720, 722, and 724. Thus, the conductors 310a and 310c can function as source and drain electrodes. One of the conductor 404a and the conductor 310b can function as a gate electrode, and the other can function as a back gate electrode.

In the oxide 406d including a channel formation region of the transistor 900, oxygen vacancies and impurities such as hydrogen and water are reduced as in the oxide 406c or the like. Thus, the threshold voltage of the transistor 900 can be higher than 0 V the off-state current can be reduced, and Icut can be noticeably reduced. Note that Icut refers to a drain current when the back gate voltage and the top gate voltage are each 0 V.

The back gate voltage of the transistor 700 is controlled by the transistor 900. For example, a top gate and a back gate of the transistor 900 are diode-connected to a source thereof, and the source of the transistor 900 and the back gate of the transistor 700 are connected to each other. When the negative potential of the back gate of the transistor 700 is held in the structure, the top gate-source voltage and the back gate-source voltage of the transistor 900 are each 0 V. Since the Icut of the transistor 900 is extremely small, the structure allows the negative potential of the back gate of the transistor 700 to be held for a long time without power supply to the transistor 700 and the transistor 900. Accordingly, the memory device including the transistor 700 and the transistor 900 can retain stored data for a long time.

In FIGS. 19 and 20, a wiring 3001 is electrically connected to a source of the transistor 800, and a wiring 3002 is electrically connected to a drain of the transistor 800. A wiring 3003 is electrically connected to one of a source and a drain of the transistor 700, a wiring 3004 is electrically connected to a top gate of the transistor 700, and a wiring 3006 is electrically connected to the back gate of transistor 700. A gate of the transistor 800 and the other of the source and the drain of the transistor 700 are electrically connected to one electrode of the capacitor 600. A wiring 3005 is electrically connected to the other electrode of the capacitor 600. A wiring 3007 is electrically connected to the source of the transistor 900, a wiring 3008 is electrically connected to the top gate of the transistor 900, a wiring 3009 is electrically connected to the back gate of the transistor 900, and a wiring 3010 is electrically connected to the drain of the transistor 900. The wiring 3006, the wiring 3007, the wiring 3008, and the wiring 3009 are electrically connected to each other.

### <Memory Device Configuration 1>

The memory devices in FIGS. 19 and 20 have a feature that the potential of the gate of the transistor 800 can be held, and thus enables writing, retaining, and reading of data as follows.

Writing and retaining of data will he described. First, the potential of the wiring 3004 is set to a potential at which the transistor 700 is on, so that the transistor 700 is turned on. Accordingly, the potential of the wiring 3003 is supplied to a node FG where the gate of the transistor 800 and the one electrode of the capacitor 600 are electrically connected to each other. That is, predetermined charge is supplied to the gate of the transistor 800 (writing). Here, one of two kinds of charge that provide different potential levels (hereinafter referred to as low-level charge and high-level charge) is supplied. After that, the potential of the wiring 3004 is set to a potential at which the transistor 700 is off, so that the transistor 700 is turned off. Thus, the charge is retained in the node FG (retaining).

Since the off-state current of the transistor 700 is small, the charge of the node FG is retained for a long time.

Next, reading of data will be described. An appropriate potential (reading potential) is supplied to the wiring 3005 while a predetermined potential (constant potential) is supplied to the wiring 3001, whereby the potential of the wiring 3002 varies depending on the amount of charge retained in the node FG. This is because in the case of using an n-channel transistor as the transistor 800, an apparent threshold voltage Vₜₕ_{_}_{II} at the time when the high-level charge is given to the gate of the transistor 800 is lower than an apparent threshold voltage Vₜₕ_{_}_{I.} at the time when the low-level charge is given to the gate of the transistor 800. Here, an apparent threshold voltage refers to the potential of the wiring 3005 which is needed to turn on the transistor 800. Thus, the potential of the wiring 3005 is set to a potential V₀ which is between Vₜₕ_{_}_{H} and Vₜₕ_{_}_{L}, whereby charge supplied to the node FG can be determined. For example, in the case where the high-level charge is supplied to the node FG in writing, the transistor 800 is turned on when the potential of the wiring 3005 becomes V₀ (>Vₜₕ_{_}_{H}). In the case where the low-level charge is supplied to the node FG in writing, the transistor 800 still remains off even when the potential of the wiring 3005 becomes V₀(<Vₜₕ_{_}_{L}). Thus, the data retained in the node FG can be read by determining the potential of the wiring 3002.

By arranging the memory devices illustrated in FIGS. 19 and 20 in a matrix, a memory cell array can be formed.

Note that in the case where memory cells are arrayed, it is necessary that data of a desired memory cell be read in read operation. For example, in the case of a NOR-type memory cell array, only data of a desired memory cell can be read by turning off the transistors 800 of memory cells from which data is not read. In this case, a potential at which the transistor 800 is turned off regardless of the charge supplied to the node FG, that is, a potential lower than Vₜₕ_{_{—hd H}} is supplied to the wiring 3005 connected to the memory cells from which data is not read. Alternatively, in the case of a NAND-type memory cell array, for example, only data of a desired memory cell can be read by turning on the transistors 800 of memory cells from which data is not read. In this case, a potential at which the transistor 800 is turned on regardless of the charge supplied to the node FG, that is, a potential higher than Vₜₕ_{_}_{L} is supplied to the wiring 3005 connected to the memory cells from which data is not read.

### <Memory Device Configuration 2>

The memory devices illustrated in FIGS. 19 and 20 do not necessarily include the transistor 800. Also in that case, data can be written and retained in a manner similar to that of the memory device described above.

For example, data reading in the memory device without the transistor 800 will be described. When the transistor 700 is turned on, the wiring 3003 which is in a floating state and the capacitor 600 are brought into conduction, and the charge is redistributed between the wiring 3003 and the capacitor 600. As a result, the potential of the wiring 3003 is changed. The amount of change in the potential of the wiring 3003 varies depending on the potential of the one electrode of the capacitor 600 (or the charge accumulated in the capacitor 600).

For example, the potential of the wiring 3003 after the charge redistribution is (C_{B}×V_{B0}×C×V)/(C_{B}+C), where V is the potential of the one electrode of the capacitor 600, C is the capacitance of the capacitor 600, C_{B} is the capacitance component of the wiring 3003, and V_{B0} is the potential of the wiring 3003 before the charge redistribution. Thus, it can be found that, assuming that the memory cell is in either of two states in which the potential of the one electrode of the capacitor 600 is V₁ and V₀ (V₁>V₀), the potential of the wiring 3003 when the potential V₁ is retained (=(C_{B}×V_{B0}+C×V₁)/(C_{B}+C)) is higher than the potential of the wiring 3003 when the potential V₀ is retained (=(C_{B}×V_{B0}+C×V₀)/(C_{B}+C)).

Then, by comparing the potential of the wiring 3003 with a predetermined potential, data can be read.

In the case of employing the configuration, a transistor using silicon may be used for a driver circuit for driving a memory cell, and a transistor using an oxide semiconductor may be stacked as the transistor 700 over the driver circuit.

When including a transistor using an oxide semiconductor and having a small off-state current, the memory device described above can retain stored data for a long time. In other words, power consumption of the memory device can be reduced because refresh operation becomes unnecessary or the frequency of refresh operation can be extremely low. Moreover, stored data can be retained for a long time even when power is not supplied (note that a potential is preferably fixed).

In the memory device, a high voltage is not needed for data writing and deterioration of elements is unlikely to occur. Unlike in a conventional nonvolatile memory, for example, it is not necessary to inject and extract electrons into and from a floating gate; thus, a problem such as deterioration of an insulator is not caused. That is, unlike a conventional nonvolatile memory, the memory device of one embodiment of the present invention does not have a limit on the number of times data can be rewritten and the reliability thereof is drastically improved. Furthermore, data is written depending on the on/off state of the transistor, whereby high-speed operation can be achieved.

Furthermore, the transistor 700 includes an oxide having a multilayer structure as an active layer as described in the above embodiment; thus, a large on-state current can be obtained. This contributes to enhancement of data writing speed and operation speed. <Memory Device Structure 1>

FIG. 19 illustrates an example of the memory device of one embodiment of the present invention. The memory device includes the transistor 900, the transistor 800, the transistor 700, and the capacitor 600. The transistor 700 is provided over the transistor 800, and the capacitor 600 is provided over the transistor 800 and the transistor 700.

The transistor 800 is provided over a substrate 811 and includes a conductor 816, an insulator 814, a semiconductor region 812 that is a part of the substrate 811, and low-resistance regions 818a and 818b functioning as source and drain regions.

The transistor 800 is either a p-channel transistor or an n-channel transistor.

It is preferable that a region of the semiconductor region 812 where a channel is formed, a region in the vicinity thereof, the low-resistance regions 818a and 818b functioning as source and drain regions, and the like include a semiconductor such as a silicon-based semiconductor, more preferably single crystal silicon. Alternatively, a material including germanium (Ge), silicon germanium (SiGe), gallium arsenide (GaAs), gallium aluminum arsenide (GaAlAs), or the like may be included. Silicon whose effective mass is controlled by applying stress to the crystal lattice and thereby changing the lattice spacing may be included. Alternatively, the transistor 800 may be a high-electron-mobility transistor (HEMT) with GaAs, GaAlAs, or the like.

The low-resistance regions 818a and 818b include an element which imparts n-type conductivity, such as arsenic or phosphorus, or an element which imparts p-type conductivity, such as boron, in addition to a semiconductor material used for the semiconductor region 812.

The conductor 816 functioning as a gate electrode can be formed using a semiconductor material such as silicon including an element which imparts n-type conductivity, such as arsenic or phosphorus, or an element which imparts p-type conductivity, such as boron, or a conductive material such as a metal material, an alloy material, or a metal oxide material.

Note that the work function of a conductor is determined by a material of the conductor, whereby the threshold voltage can be adjusted. Specifically, it is preferable to use titanium nitride, tantalum nitride, or the like as the conductor. Furthermore, in order to ensure the conductivity and embeddability of the conductor, it is preferable to use a laminated layer of metal materials such as tungsten and aluminum as the conductor. In particular, tungsten is preferable in terms of heat resistance.

Note that the transistors 800 illustrated in FIGS. 19 and 20 is just examples and are not limited to the structures illustrated therein; an appropriate transistor may be used in accordance with a circuit configuration or a driving method.

An insulator 820, an insulator 822, an insulator 824, and an insulator 826 are stacked in this order so as to cover the transistor 800.

The insulator 820, the insulator 822, the insulator 824, and the insulator 826 can be formed using, for example, silicon oxide, silicon oxynitride, silicon nitride oxide, silicon nitride, aluminum oxide, aluminum oxynitride, aluminum nitride oxide, aluminum nitride, or the like.

The insulator 822 functions as a planarization film for eliminating a level difference caused by the transistor 800 or the like underlying the insulator 822. The top surface of the insulator 822 may be planarized by planarization treatment using a CMP method or the like to increase the level of planarity.

The insulator 824 is preferably formed using a film with a barrier property that prevents hydrogen and impurities from diffusing from the substrate 811, the transistor 800, or the like into regions where the transistor 700 and the transistor 900 are provided. A barrier property refers to a function of inhibiting the diffusion of impurities typified by hydrogen and water. For example, the diffusion length of hydrogen in the film with a barrier property at 350° C. or at 400° C. Is less than or equal to 50 nm per hour, preferably less than or equal to 30 nm per hour, more preferably less than or equal to 20 nm per hour.

As an example of the film having a barrier property with respect to hydrogen, silicon nitride formed by a CVD method can be given. The diffusion of hydrogen into a semiconductor element including an oxide semiconductor, such as the transistor 700, degrades the characteristics of the semiconductor element in some cases. Therefore, a film that inhibits the diffusion of hydrogen is preferably provided between the transistors 700 and 900 and the transistor 800. Specifically, the film that inhibits the diffusion of hydrogen is a film from which hydrogen is unlikely to be released.

The released amount of hydrogen can be measured by TDS, for example. The amount of hydrogen released from the insulator 824 that is converted into hydrogen molecules per unit area of the insulator 824 is less than or equal to 2×10¹⁵ molecules/cm², preferably less than or equal to 1×10¹⁵ molecules/cm², more preferably 5×10¹⁴ molecules/cm² in TDS analysis in the range from 50° C. to 500° C., for example.

Note that the dielectric constant of the insulator 826 is preferably lower than that of the insulator 824. For example, the relative dielectric constant of the insulator 826 is preferably lower than 4, more preferably lower than 3. For example, the relative dielectric constant of the insulator 824 is preferably 0.7 times or less that of the insulator 826, more preferably 0.6 times or less that of the insulator 826. In the case where a material with a low dielectric constant is used for an interlayer film, the parasitic capacitance between wirings can be reduced.

A conductor 828, a conductor 830, and the like that are electrically connected to the capacitor 600 or the transistor 700 are embedded in the insulator 820, the insulator 822, the insulator 824, and the insulator 826. Note that the conductor 828 and the conductor 830 each function as a plug or a wiring. Note that a plurality of structures of conductors functioning as plugs or wirings are collectively denoted by the same reference numeral in some cases, as described later. Furthermore, in this specification and the like, a wiring and a plug electrically connected to the wiring may be a single component. That is, there are cases where a part of a conductor functions as a wiring and a part of a conductor functions as a plug.

As a material of each of plugs and wirings (e.g., the conductor 828 and the conductor 830), a conductive material such as a metal material, an alloy material, a metal nitride material, or a metal oxide material can be used in a single-layer structure or a layered structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 826 and the conductor 830. For example, in FIG. 19, an insulator 850, an insulator 852, and an insulator 854 are stacked in this order. Furthermore, a conductor 856 is formed in the insulator 850, the insulator 852, and the insulator 854. The conductor 856 functions as a plug or a wiring. Note that the conductor 856 can be formed using a material similar to that for the conductor 828 and the conductor 830.

Note that for example, the insulator 850 is preferably formed using an insulator having a barrier property with respect to hydrogen, like the insulator 824. Furthermore, the conductor 856 preferably includes a conductor having a barrier property with respect to hydrogen. The conductor having a barrier property with respect to hydrogen is formed particularly in an opening portion of the insulator 850 having a harrier property with respect to hydrogen. In such a structure, the transistor 800 can be separated from the transistors 700 and 900 by a barrier layer, so that the diffusion of hydrogen from the transistor 800 to the transistors 700 and 900 can be inhibited.

Note that as the conductor having a barrier property with respect to hydrogen, tantalum nitride is preferably used, for example. By stacking tantalum nitride and tungsten, which has high conductivity, the diffusion of hydrogen from the transistor 800 can be inhibited while the conductivity of a wiring is ensured. In this case, a tantalum nitride layer having a barrier property with respect to hydrogen is preferably in contact with the insulator 850 having a barrier property with respect to hydrogen.

An insulator 858, an insulator 710, the insulator 712, the insulator 714, and the insulator 716 are stacked in this order over the insulator 854. A material having a barrier property with respect to oxygen or hydrogen is preferably used for any of the insulator 858, the insulator 710, the insulator 712, the insulator 714, and the insulator 716,

The insulator 858, the insulator 712, and the insulator 714 are each preferably formed using, for example, a film having a barrier property that prevents hydrogen or impurities from diffusing from the substrate 811, a region where the transistor 800 is provided, or the like into the regions where the transistor 700 and the transistor 900 are provided. Therefore, the insulator 858, the insulator 712, and the insulator 714 can be formed using a material similar to that for the insulator 824.

As an example of the film having a barrier property with respect to hydrogen, silicon nitride deposited by a CVD method can be given. The diffusion of hydrogen into a semiconductor element including an oxide semiconductor, such as the transistor 700, degrades the characteristics of the semiconductor element in some cases. Therefore, a film that inhibits the diffusion of hydrogen is preferably provided between the transistors 700 and 900 and the transistor 800. Specifically, the film that inhibits the diffusion of hydrogen is a film from which hydrogen is unlikely to be released.

As the film having a barrier property with respect to hydrogen, for example, as each of the insulator 712 and the insulator 714, a metal oxide such as aluminum oxide, hafnium oxide, or tantalum oxide is preferably used.

In particular, aluminum oxide has an excellent blocking effect that prevents the passage of oxygen and impurities such as hydrogen and moisture which cause a change in electrical characteristics of the transistor. Accordingly, the use of aluminum oxide can prevent entry of impurities such as hydrogen and moisture into the transistors 700 and 900 in and after a manufacturing process of the transistor. In addition, release of oxygen from the oxide in the transistor 700 can be prevented. Therefore, aluminum oxide is suitably used as a protective film for the transistors 700 and 900.

In addition, the insulator 710 and the insulator 716 can be formed using a material similar to that for the insulator 820. The use of a material with a relatively low dielectric constant for the insulators can reduce the parasitic capacitance between wirings. For example, a silicon oxide film, a silicon oxynitride film, or the like can be used as the insulator 716.

A conductor 718, conductors included in the transistor 700 and the transistor 900, and the like are embedded in the insulator 858, the insulator 710, the insulator 712, the insulator 714, and the insulator 716. Note that the conductor 718 functions as a plug or a wiring that is electrically connected to the capacitor 600 or the transistor 800. The conductor 718 can be formed using a material similar to that for the conductor 828 and the conductor 830.

In particular, the conductor 718 in a region in contact with the insulator 858, the insulator 712, and the insulator 714 is preferably a conductor having a barrier property with respect to oxygen, hydrogen, and water. In such a structure, the transistor 800 and the transistor 700 can be completely separated by the layer having a barrier property with respect to oxygen, hydrogen, and water, so that the diffusion of hydrogen from the transistor 800 into the transistors 700 and 900 can be prevented.

The transistor 700 and the transistor 900 are provided over the insulator 716. An insulator 782 and an insulator 784 are provided over the transistor 700 and the transistor 900. The insulator 782 and the insulator 784 can be formed using a material similar to that for the insulator 824. Thus, the insulator 782 and the insulator 784 function as protective films for the transistor 700 and the transistor 900. Furthermore, it is preferred that openings be formed in the insulators 716, 720, 722, 724, 772, 774, and 780 and the insulators 714 and 782 be in contact with each other as illustrated in FIG. 19. In such a structure, the transistor 700 and the transistor 900 can be sealed with the insulator 714 and the insulator 782, preventing entry of impurities such as hydrogen and water.

An insulator 610 is provided over the insulator 784. The insulator 610 can be formed using a material similar to that for the insulator 820. The use of a material with a relatively low dielectric constant for the insulator can reduce the parasitic capacitance between wirings. For example, a silicon oxide film, a silicon oxynitride film, or the like can be used as the insulator 610.

A conductor 785 and the like are embedded in the insulator 720, the insulator 722, the insulator 724, the insulator 772, the insulator 774, and the insulator 610.

Note that the conductor 785 functions as a plug or a wiring that is electrically connected to the capacitor 600, the transistor 700, or the transistor 800. The conductor 785 can be formed using a material similar to that for the conductor 828 and the conductor 830.

For example, in the case where the conductor 785 is formed to have a layered structure, it preferably includes a conductor that is unlikely to he oxidized (that has high oxidation resistance). It is particularly preferred that a conductor having high oxidation resistance be provided so as to he in contact with the insulator 724 including an excess oxygen region. Such a structure permits inhibition of absorption of excess oxygen from the insulator 724 by the conductor 785. Furthermore, the conductor 785 preferably includes a conductor having a barrier property with respect to hydrogen. In particular, when a conductor having a barrier property with respect to impurities such as hydrogen is provided in contact with the insulator 724 including an excess oxygen region, the diffusion of impurities in the conductor 785 and part of the conductor 785 and the diffusion of impurities from the outside through the conductor 785 can be inhibited.

A conductor 787, the capacitor 600, and the like are provided over the insulator 610 and the conductor 785. The capacitor 600 includes a conductor 612, an insulator 630, an insulator 632, an insulator 634, and a conductor 616. The conductor 612 and the conductor 616 function as the electrodes of the capacitor 600, and the insulator 630, the insulator 632, and the insulator 634 function as dielectrics of the capacitor 600.

Note that the conductor 787 functions as a plug or a wiring that is electrically connected to the capacitor 600, the transistor 700, or the transistor 800. The conductor 612 functions as the one electrode of the capacitor 600. The conductor 787 and the conductor 612 can be formed at the same time.

For the conductor 787 and the conductor 612, a metal film containing an element selected from molybdenum, titanium, tantalum, tungsten, aluminum, copper, chromium, neodymium, and scandium; a metal nitride film containing any of the above elements as its component (e.g., a tantalum nitride film, a titanium nitride film, a molybdenum nitride film, or a tungsten nitride film); or the like can be used. Alternatively, a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added may be used.

The insulator 630, the insulator 632, and the insulator 634 can each be formed to have a single-layer structure or a layered structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

For example, the use of a high dielectric constant (high-k) material, such as aluminum oxide, for the insulator 632 can increase the capacitance per unit area of the capacitor 600. Furthermore, a material having high dielectric strength, such as silicon oxynitride, is preferably used for the insulator 630 and the insulator 634. When a ferroelectric is located between insulators with high dielectric strength, electrostatic breakdown of the capacitor 600 can be suppressed and the capacitor can have large capacitance.

The conductor 616 is provided so as to cover the top and side surfaces of the conductor 612 with the insulator 630, the insulator 632, and the insulator 634 therebetween. In the structure where the side surfaces of the conductor 612 are wrapped by the conductor 616 with the insulators therebetween, capacitance is also formed on the side surfaces of the conductor 612, resulting in an increase in the capacitance per unit projected area of the capacitor. Thus, the memory device can be reduced in area, highly integrated, and miniaturized.

Note that the conductor 616 can be formed using a conductive material such as a metal material, an alloy material, or a metal oxide material. It is preferable to use a high-melting-point material which has both heat resistance and conductivity, such as tungsten or molybdenum, and it is particularly preferable to use tungsten. In the case where the conductor 616 is formed concurrently with another component such as a conductor, Cu, Al, or the like, which is a low-resistance metal material, may be used.

An insulator 650 is provided over the conductor 616 and the insulator 634. The insulator 650 can be formed using a material similar to that for the insulator 820. The insulator 650 may function as a planarization film that covers roughness due to underlying layers.

The above is the description of the structure example. With the use of the structure, a change in electrical characteristics can be suppressed and reliability can be improved in a memory device including a transistor including an oxide semiconductor. Alternatively, a transistor including an oxide semiconductor with a large on-state current can be provided. A transistor including an oxide semiconductor with a small off-state current can be provided. Alternatively, a memory device with low power consumption can be provided.

### MODIFICATION EXAMPLE 1

FIG. 20 illustrates a modification example of the memory device. FIG. 20 is different from FIG. 19 in the structure of the transistor 800.

In the transistor 800 illustrated in FIG. 20, the semiconductor region 812 (part of the substrate 811) in which a channel is formed includes a protruding portion. Furthermore, the conductor 816 is provided so as to cover the top and side surfaces of the semiconductor region 812 with the insulator 814 therebetween. Note that the conductor 816 may be formed using a material for adjusting the work function. The transistor 800 is also referred to as a FIN transistor because it utilizes a protruding portion of the semiconductor substrate. An insulator functioning as a mask for forming the protruding portion may be provided in contact with the top surface of the protruding portion. Although the case where the protruding portion is formed by processing part of the semiconductor substrate is described here, a semiconductor film having a protruding portion may be formed by processing an SOI substrate.

The use of a combination of the transistor 800 and the transistor 700 that have the structure enables a reduction in area, high integration, and miniaturization.

With the use of the structure, a change in electrical characteristics can be suppressed and reliability can be improved in a memory device including a transistor including an oxide semiconductor. Furthermore, a transistor including an oxide semiconductor with a large on-state current can be provided. Furthermore, a transistor including an oxide semiconductor with a small off-state current can be provided. Furthermore, a memory device with low power consumption can be provided.

At least part of this embodiment can be implemented in combination with any of the other embodiments described in this specification as appropriate.

### EXPLANATION OF REFERENCE

11a: sputtering target, 12: sputtering target, 50a: backing plate, 50c: backing plate, 66: shutter, 67: cut portion, 100: transistor, 100a: portion, 100b: portion, 102: substrate, 104: insulator, 106: conductor, 108: oxide, 108a: oxide, 108b: oxide, 108c: oxide, 108n: region, 110: insulator, 112: conductor, 116: insulator, 118: insulator, 120a: conductor, 120b: conductor, 141a: opening, 141b: opening, 143: opening, 301: insulator, 302: insulator, 303: insulator, 310: conductor, 310a: conductor, 310b: conductor, 310c: conductor, 400: substrate, 401a: insulator, 401b: insulator, 402: insulator, 404: conductor, 404a: conductor, 406a: oxide, 406a1: oxide, 406b: oxide, 406b1: oxide, 406b1n: oxide, 406b1w: oxide, 406bn: oxide, 406bn_n: oxide, 406bn_1: oxide, 406bn_2: oxide, 406bw: oxide, 406bw_n: oxide, 406bw_1: oxide, 406bw_2: oxide, 406c: oxide, 406d: oxide, 408a: insulator, 408b: insulator, 410: insulator, 412: insulator, 412a: insulator, 416a1: conductor, 416a2: conductor, 417a1: barrier film, 417a2: barrier film, 500: transistor, 502: substrate, 504: conductor, 506: insulator, 507: insulator, 508: oxide, 508a: oxide, 508b: oxide, 508c: oxide, 508n: region, 512a: conductor, 512b: conductor, 514: insulator, 516: insulator, 518: insulator, 520a: conductor, 520b: conductor, 542a: opening, 542b: opening, 542c: opening, 600: capacitor, 610: insulator, 612: conductor, 616: conductor, 630: insulator, 632: insulator, 634: insulator, 650: insulator, 700: transistor, 710: insulator, 712: insulator, 714: insulator, 716: insulator, 718: conductor, 720: insulator, 722: insulator, 724: insulator, 772: insulator, 774: insulator, 780: insulator, 782: insulator, 784: insulator, 785: conductor, 787: conductor, 800: transistor, 811: substrate, 812: semiconductor region, 814: insulator, 816: conductor, 818a: low-resistance region, 818b: low-resistance region, 820: insulator, 822: insulator, 824: insulator, 826: insulator, 828: conductor, 830: conductor, 850: insulator, 852: insulator, 854: insulator, 856: conductor, 858: insulator, 900: transistor, 3001: wiring, 3002: wiring, 3003: wiring, 3004: wiring, 3005: wiring, 3006: wiring, 3007: wiring, 3008: wiring, 3009: wiring, 3010: wiring

This application is based on Japanese Patent Application serial no. 2016-127100 filed with Japan Patent Office on Jun. 27, 2016 and Japanese Patent Application serial no. 2016-140980 filed with Japan Patent Office on Jul. 18, 2016, the entire contents of which are hereby incorporated by reference.

1. A transistor comprising:
a gate electrode;
a first conductor;
a second conductor;
a gate insulator; and
a metal oxide,
wherein the gate insulator is located between the gate electrode and the metal oxide,
wherein the gate electrode includes a region overlapping with the metal oxide with the gate insulator therebetween,
wherein the first conductor and the second conductor each include a region in contact with top and side surfaces of the metal oxide,
wherein the metal oxide has a layered structure in which oxide layers each having a first band gap and an oxide layer having a second band gap and being adjacent to the oxide layer having the first band gap are alternately stacked in a thickness direction, and
wherein the first band gap is smaller than the second band gap.

2. The transistor according to claim 1, wherein a difference between the second band gap and the first band gap is greater than or equal to 0.3 eV and less than or equal to 1.3 eV.

3. The transistor according to claim 1, wherein a difference in conduction band minimum between the oxide layer having the second band gap and the oxide layer having the first band gap is greater than or equal to 0.3 eV and less than or equal to 1.3 eV.

4. The transistor according to claim 1,
wherein the oxide layers each having the first band gap include either or both of indium and zinc, and
wherein the oxide layer having the second band gap includes either or both of indium and zinc and an element M, the element M being one or more of aluminum, gallium, silicon, boron, yttrium, copper, vanadium, beryllium, titanium, iron, nickel, germanium, zirconium, molybdenum, lanthanum, cerium, neodymium, hafnium, tantalum, tungsten, and magnesium.

5. The transistor according to claim 1,
wherein the oxide layers each having the first band gap include either or both of indium and zinc and an element M, the element M being one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium,
wherein the oxide layer having the second band gap includes either or both of indium and zinc and the element M, and
wherein the oxide layer having the second hand gap includes more the elements M than the oxide layers each having the first band gap.

6. The transistor according to claim 1, wherein a thickness of the oxide layer having the first band gap is greater than or equal to 0.5 nm and less than or equal to 10 nm.

7. The transistor according to claim 1, wherein a thickness of the oxide layer having the first band gap is greater than or equal to 0.5 nm and less than or equal to 2.0 nm.

8. The transistor according to claim 1, wherein a thickness of the oxide layer having the second hand gap is greater than or equal to 0.1 nm and less than or equal to 10 nm.

9. The transistor according to claim 1, wherein a thickness of the oxide layer having second band gap is greater than or equal to 0.1 nm and less than or equal to 3.0 nm.

10. The transistor according to claim 1, wherein a distance between an edge of the first conductor and an edge of the second conductor is greater than or equal to 10 mn and less than or equal to 300 nm.

11. The transistor according to claim 1, wherein a width of the gate electrode is greater than or equal to 10 nm and less than or equal to 300 nm.

12. The transistor according to claim 1, wherein a carrier density in the oxide layer having the first band gap is greater than or equal to 6×10¹⁸ cm⁻³ and less than or equal to 5×10²⁰ cm⁻³.

13. The transistor according to claim 1, wherein the oxide layer having the first band gap is degenerate.

14. The transistor according to claim 1, wherein the oxide layer having the first band gap includes either or both of indium and zinc.

15. The transistor according to claim 1, wherein the oxide layer having the first band gap includes either or both of indium and zinc and the element M.

16. The transistor according to claim 1, wherein the oxide layer having the second band gap includes indium, zinc, and the element M.

17. The transistor according to claim 1, wherein the oxide layer having the first band gap includes more hydrogen than the oxide layer having the second hand gap.

18. The transistor according to claim 17, wherein a hydrogen concentration in the oxide layer having the first hand gap is greater than 1×10¹⁹ cm⁻³.

19. The transistor according to claim 1, wherein the number of the oxide layers each having the first band gap in the metal oxide is three or more and ten or less.

20. A transistor comprising:
a gate electrode;
a first conductor;
a second conductor;
a gate insulator;
a first metal oxide;
a second metal oxide; and
a third metal oxide,
wherein the gate insulator is located between the gate electrode and the first metal oxide,
wherein the gate electrode includes a region overlapping with the second metal oxide with the gate insulator and the first metal oxide therebetween,
wherein the first conductor and the second conductor each include a region in contact with top and side surfaces of the second metal oxide,
wherein the second metal oxide includes a region in contact with a top surface of the third metal oxide,
wherein the second metal oxide has a layered structure in which oxide layers each having a first band gap and an oxide layer having a second band gap and being adjacent to the oxide layer having the first band gap are alternately stacked in a thickness direction, and
wherein the first band gap is smaller than the second band gap.

21. The transistor according to claim 20, wherein a difference between the second band gap and the first band gap is greater than or equal to 0.3 eV and less than or equal to 1.3 eV.

22. The transistor according to claim 20,
wherein the second metal oxide includes a channel formation region, and
wherein the first metal oxide extends in a channel width direction of the channel formation region so as to cover the second metal oxide.

23. The transistor according to claim 20,
wherein the number of the oxide layers each having the first band gap in the second metal oxide is three or more and ten or less.

24. The transistor according to claim 20,
wherein band gaps of the first metal oxide and a third metal oxide are each larger than a band yap of the second metal oxide.
